(19) United States
(12) Patent Application Publication
(10) Pub. No.: US 2025/0040301 A1
(43) Pub. Date: Jan. 30, 2025

(54) LIGHT-EMITTING ELEMENT, DISPLAY DEVICE INCLUDING THE SAME, AND METHOD OF FABRICATING LIGHT-EMITTING ELEMENT

(71) Applicant: Samsung Display Co., LTD., Yongin-si (KR)

(72) Inventors: Sang Tae LEE, Yongin-si (KR); Seok Jin KANG, Yongin-si (KR); Sang Jo KIM, Yongin-si (KR); Jeong Hun HEO, Yongin-si (KR)

(73) Assignee: Samsung Display Co., LTD., Yongin-si (KR)

(21) Appl. No.: 18/590,971

(22) Filed: Feb. 29, 2024

(30) Foreign Application Priority Data
Jul. 25, 2023 (KR) 10-2023-0096492

(51) Int. Cl. H01L 33/30; H01L 25/075; H01L 33/00; H01L 33/06

(52) U.S. Cl. CPC H01L 33/30; H01L 25/0753; H01L 33/0062; H01L 33/06

(57) ABSTRACT

A light-emitting element includes a first semiconductor layer doped to a first conductivity type, an active layer disposed on the first semiconductor layer, a second semiconductor layer disposed on the active layer, the second semiconductor layer doped to a second conductivity type, and a passivation layer surrounding surfaces of the active layer, the passivation layer including a side surface of the active layer, and the passivation layer includes a semiconductor material that matches a lattice of a semiconductor material contained in the active layer, the semiconductor material has a band gap energy higher than that of the semiconductor material contained in the active layer.

### CROSS-REFERENCE TO RELATED APPLICATION(S)

This application claims priority to and benefits of Korean Patent Application No. 10-2023-0096492 under 35 U.S.C. § 119 filed on Jul. 25, 2023, in the Korean Intellectual Property Office, the entire contents of which are incorporated herein by reference.

### BACKGROUND

### 1. Technical Field

Embodiments relate to a light-emitting element, a display device including the same, and a method of fabricating the light-emitting element.

### 2. Description of the Related Art

Display devices become more and more important as multimedia technology evolves. Accordingly, a variety of display devices such as liquid-crystal display devices and light-emitting display devices are currently being developed. Among these, light-emitting display devices using light-emitting elements are employed by a variety of types of electronic devices including virtual reality (VR) devices and augmented reality (AR) devices in addition to portable electronic devices and televisions.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Aspects of the disclosure provide a light-emitting element with improved luminous efficiency, a display device including the same, and a method of fabricating the light-emitting element.

However, aspects of the disclosure are not restricted to the ones set forth herein. The above and other aspects of the disclosure will become more apparent to one of ordinary skill in the art to which the disclosure pertains by referencing the detailed description of the disclosure given below.

According to an aspect of the disclosure, there is provided a light-emitting element that may include a first semiconductor layer doped to a first conductivity type; an active layer disposed on the first semiconductor layer; a second semiconductor layer disposed on the active layer, the second semiconductor layer doped to a second conductivity type; and a passivation layer surrounding surfaces of the active layer, the passivation layer including a side surface of the active layer, wherein the passivation layer may include a semiconductor material that matches a lattice of a semiconductor material contained in the active layer, the semiconductor material has a band gap energy higher than that of the semiconductor material contained in the active layer.

In an embodiment, the active layer may include a quantum well layer containing GaInP and a barrier layer containing AlGaInP, and the passivation layer may be formed as a semiconductor layer containing AlInP.

In an embodiment, the passivation layer may be formed as an intrinsic semiconductor layer containing AlInP.

In an embodiment, the passivation layer may be disposed between the first semiconductor layer and the second semiconductor layer, and the passivation layer may entirely surround the surfaces of the active layer including a first bottom surface, a second bottom surface, and the side surface of the active layer.

In an embodiment, the passivation layer may include a first passivation layer disposed between the first semiconductor layer and the active layer; a second passivation layer disposed on a peripheral region of the first passivation layer and contacting the side surface of the active layer; a third passivation layer disposed on a central region of the first passivation layer and contacting the first bottom surface of the active layer; and a fourth passivation layer disposed on the active layer and contacting the second bottom surface of the active layer.

In an embodiment, the light-emitting element may further include an etch stop layer disposed between the first passivation layer and the second passivation layer and surrounding the third passivation layer.

In an embodiment, the etch stop layer may include an opening overlapping the active layer.

In an embodiment, the etch stop layer may be formed as an intrinsic semiconductor layer containing AlGaAs.

In an embodiment, the passivation layer may include a side surface including an inclined surface.

In an embodiment, the light-emitting element may further include an insulating layer disposed at a peripheral region of the passivation layer.

According to an aspect of the disclosure, there is provided a display device that may include pixels, each of the pixels including a first electrode, a second electrode, and a light-emitting element electrically connected between the first electrode and the second electrode, wherein the light-emitting elements may include a first semiconductor layer doped to a first conductivity type, an active layer disposed on the first semiconductor layer, a second semiconductor layer disposed on the active layer, the second semiconductor layer doped to a second conductivity type, and a passivation layer surrounding surfaces of the active layer, the passivation layer including a side surface of the active layer, and wherein the passivation layer may include a semiconductor material that matches a lattice of a semiconductor material contained in the active layer, the semiconductor material has a band gap energy higher than that of the semiconductor material contained in the active layer.

In an embodiment, the active layer may include a quantum well layer containing GaInP and a barrier layer containing AlGaInP, and the passivation layer may be formed as a semiconductor layer containing AlInP.

In an embodiment, the passivation layer may be disposed between the first semiconductor layer and the second semiconductor layer, and the passivation layer may entirely surround the surfaces of the active layer including a first bottom surface, a second bottom surface, and the side surface of the active layer.

In an embodiment, the passivation layer may include a first passivation layer disposed between the first semiconductor layer and the active layer, a second passivation layer disposed on a peripheral region of the first passivation layer and contacting the side surface of the active layer, a third passivation layer disposed on a central region of the first passivation layer and contacting the first bottom surface of the active layer, and a fourth passivation layer disposed on the active layer and contacting the second bottom surface of the active layer.

In an embodiment, the light-emitting element further may include an etch stop layer disposed between the first passivation layer and the second passivation layer and surrounding the third passivation layer.

In an embodiment, the passivation layer may include a side surface including an inclined surface.

According to an aspect of the disclosure, there is provided a method of fabricating a light-emitting element, the method including sequentially forming a first semiconductor layer, a first passivation layer, an etch stop layer, a second passivation layer, and an insulating layer on a substrate; etching a part of the insulating layer to expose a part of the second passivation layer; exposing a part of the etch stop layer by etching the exposed part of the second passivation layer; exposing a part of the first passivation layer by etching the exposed part of the etch stop layer; and sequentially forming a third passivation layer, an active layer, a fourth passivation layer, and a second semiconductor layer on the exposed part of the first passivation layer.

In an embodiment, the first passivation layer, the second passivation layer, the third passivation and the fourth passivation layer may be formed by using a semiconductor material that matches a lattice of a semiconductor material contained in the active layer, the semiconductor material has a band gap energy higher than that of the semiconductor material contained in the active layer.

In an embodiment, the forming of the active layer may include alternately forming a barrier layer containing AlGaInP and a quantum well layer containing GaInP on the third passivation layer, and the first passivation layer, the second passivation layer, the third passivation layer and the fourth passivation layer may be formed using AlInP as a material.

In an embodiment, the method may further include forming a plurality of light-emitting elements simultaneously on the substrate, and separating the light-emitting elements from one another at least partially after the second semiconductor layer has been formed.

Aspects of the disclosure provide a light-emitting element in which surfaces of an active layer may be surrounded with a passivation layer including a semiconductor material that matches a lattice of a semiconductor material contained in the active layer. By doing so, it is possible to suppress or reduce surface defects of the light-emitting element and to improve the emission efficiency of the light-emitting element.

It is possible to form the passivation layer with a semiconductor material that has a higher band gap energy than that of the semiconductor material contained in the active layer. By doing so, it is possible to suppress or reduce non-emissive recombination of electrons and holes and to improve the emission efficiency of the light-emitting element.

A display device according to embodiments may include pixels including the light-emitting elements. Accordingly, it is possible to improve the emission efficiency of the pixels and the display device including the pixels.

However, effects according to embodiments of the disclosure are not limited to those described above and various other effects are incorporated herein.

### BRIEF DESCRIPTION OF THE DRAWINGS

The above and other aspects and features of the disclosure will become more apparent by describing in detail embodiments thereof with reference to the attached drawings, in which:

FIG. 1 is a schematic cross-sectional view showing a light-emitting element according to an embodiment.

FIG. 2 is an enlarged, schematic cross-sectional view showing area A1 of FIG. 1.

FIG. 3 is a graph showing band gap energy versus lattice constant of example semiconductor materials.

FIG. 4 is a schematic cross-sectional view showing a light-emitting element according to an embodiment.

FIG. 5 is a schematic cross-sectional view showing a light-emitting element according to an embodiment.

FIG. 6 is a schematic cross-sectional view showing a light-emitting element according to an embodiment.

FIGS. 7 to 19 are schematic cross-sectional views showing a method of fabricating a light-emitting element according to an embodiment.

FIGS. 20 to 24 are schematic cross-sectional views showing a method of fabricating a light-emitting element according to an embodiment.

FIGS. 25 to 27 are schematic cross-sectional views showing a method of fabricating light-emitting elements according to embodiments.

FIG. 28 is a schematic perspective view of a display device according to an embodiment.

FIG. 29 is a schematic plan view showing an example of area A2 of FIG. 28.

FIG. 30 is a schematic plan view showing an example of area A2 of FIG. 28.

FIG. 31 is a schematic cross-sectional view showing an example of a cross section of a display panel, taken along line X1-X1′ of FIG. 30.

FIG. 32 is a view showing an example of a virtual reality device including a display device according to an embodiment.

FIG. 33 is a view showing an example of a smart device including a display device according to an embodiment.

FIG. 34 is a view showing an example of an instrument cluster and a center fascia for a vehicle which include display devices according to an embodiment.

FIG. 35 is a view showing an example of a transparent display device including a display device according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will also be understood that when an element or a layer is referred to as being “on” another element or layer, it can be directly on the other element or layer, or intervening layers may also be present. The same reference numbers indicate the same components throughout the specification.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical or electrical connection or coupling.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Features of each of various embodiments may be partially or entirely combined with each other and may technically variously interwork with each other, and respective embodiments may be implemented independently of each other or may be implemented together in association with each other.

Hereinafter, embodiments will be described in detail with reference to the accompanying drawings.

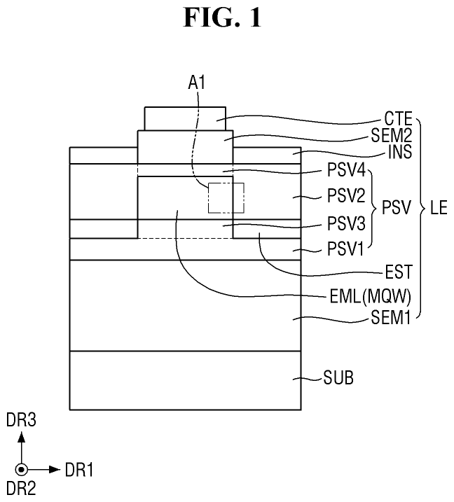

FIG. 1 is a schematic cross-sectional view showing a light-emitting element LE according to an embodiment. Although the light-emitting element LE is disposed on a substrate SUB in FIG. 1, the embodiments are not limited thereto. For example, the light-emitting element LE may be fabricated on the substrate SUB and may be separated from the substrate SUB.

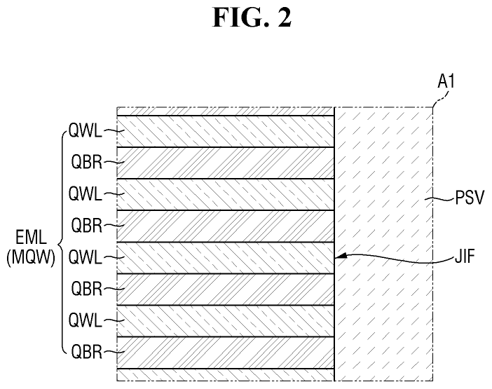

FIG. 2 is an enlarged, schematic cross-sectional view showing area A1 of FIG. 1. For example, FIG. 2 shows a structure of an active layer EML shown in FIG. 1 and an interface JIF between the active layer EML and a passivation layer PSV.

Referring to FIGS. 1 and 2, the light-emitting element LE may include a first semiconductor layer SEM1, the active layer EML, and a second semiconductor layer SEM2 sequentially disposed and/or stacked on the substrate SUB, and may include the passivation layer PSV surrounding the active layer EML. According to the embodiment, the light-emitting element LE may further include an etch stop layer EST disposed around the active layer EML and the passivation layer PSV, an insulating layer INS disposed on a part of the passivation layer PSV, and a contact electrode CTE disposed on the second semiconductor layer SEM2.

Although the contact electrode CTE is included in the light-emitting element LE in the example shown in FIG. 1, the embodiments are not limited thereto. For example, the contact electrode CTE may be formed separately from the light-emitting element LE and may be provided or disposed on one end or an end of the light-emitting element LE.

The substrate SUB (also referred to as a growth substrate or a fabrication substrate) may be a semiconductor substrate for forming the light-emitting element LE. The substrate SUB may be a fabrication substrate or wafer suitable for epitaxial growth (or epitaxy). For example, the first semiconductor layer SEM1, the passivation layer PSV, the active layer EML and the second semiconductor layer SEM2 of the light-emitting element LE may be formed on the substrate SUB by epitaxial growth.

According to an embodiment, the substrate SUB may be a substrate including a material such as GaAs, silicon (Si), sapphire, SiC, GaN, and ZnO. For example, the substrate SUB may be a semiconductor substrate made of GaAs.

Besides, the substrate SUB may be a substrate of various types and/or materials. For example, the type or material of the substrate SUB is not particularly limited as long as epitaxial growth for fabricating the light-emitting element LE can be performed well. According to an embodiment, the substrate SUB may be finally separated from the light-emitting element LE after being used as the substrate for epitaxial growth for fabricating the light-emitting element LE. For example, after forming light-emitting elements LE at the same time by the epitaxial growth on the substrate SUB, the light-emitting elements LE may be separated from the substrate SUB.

The first semiconductor layer SEM1, the active layer EML and the second semiconductor layer SEM2 may be sequentially disposed and/or stacked on the substrate SUB in the third direction DR3. According to an embodiment, the third direction DR3 may be the thickness direction (or height direction) of the light-emitting element LE.

According to an embodiment, the light-emitting element LE may be an inorganic light-emitting element formed of an inorganic material. For example, the light-emitting element LE may be an organic light-emitting diode (inorganic LED) formed of phosphide semiconductor materials such as GaP, GaInP, AlGaP, AlInP, AlGaInP, AlP and InP; nitride semiconductor materials such as GaN, AlGaN, InGaN, AlInGaN, AlN and InN; or other inorganic materials. According to an embodiment, the light-emitting element LE may be a red LED that emits red light and is formed of phosphide semiconductor materials including GaInP, AlInP and AlGaInP.

According to an embodiment, the light-emitting element LE may be a vertical micro LED extended in the third direction DR3. For example, the light-emitting element LE may be a micro LED that has a length in the first direction DR1 (for example, horizontal length), a length in the second direction DR2 (for example, vertical length), and a length in the third direction DR3 (for example, thickness or height) of several to hundreds of micrometers (μm). According to an embodiment, each of the length of the light-emitting element LE in the first direction DR1, the length in the second direction DR2 and the length in the third direction DR3 may be equal to or less than about 100 μm. It should be noted that the size of the light-emitting element LE is not limited, and the light-emitting element LE may be fabricated in various sizes.

According to an embodiment, the light-emitting element LE may include a side surface substantially perpendicular to the substrate SUB, and may have a generally rectangular cross-section. For example, the light-emitting element LE may have a rectangular or square cross-section in which the width of the upper surface is substantially equal to the width of the lower surface, except for a portion where the contact electrode CTE or the like protrudes.

It should be noted that the shape of the light-emitting element LE is not limited, and the light-emitting element LE may be fabricated in various shapes. For example, the light-emitting element LE may have a trapezoidal (or inverted trapezoidal) cross-sectional shape at least partially.

The light-emitting element LE may have various shapes when viewed from the top. For example, when viewed on a plane defined by the first direction DR1 and the second direction DR2 (for example, on a cross section), the light-emitting element LE may have a quadrangular shape including a square or rectangle, a non-rectangular shape including a circle or an ellipse, or other shapes.

The first semiconductor layer SEM1 may be disposed on the substrate SUB. The first semiconductor layer SEM1 may be formed of an inorganic material such as a phosphide semiconductor material and a nitride semiconductor material. For example, the first semiconductor layer SEM1 may include phosphide semiconductor materials such as GaP, GaInP, AlGaP, AlInP, AlGaInP, AlP and InP; nitride semiconductor materials such as GaN, AlGaN, InGaN, AlInGaN, AlN and InN; or other inorganic materials.

The first semiconductor layer SEM1 may be doped to a first conductivity type. For example, the first semiconductor layer SEM1 may include a semiconductor material doped with a first conductivity type dopant. According to an embodiment, the first semiconductor layer SEM1 may be an n-type semiconductor layer doped with an n-type dopant (for example, Si, Ge, Sn, or other n-type dopants) used to form an n-type semiconductor.

According to an embodiment, the first semiconductor layer SEM1 may be a single-layer or multi-layer semiconductor layer including at least one of: an n-GaInP semiconductor layer, an n-AlGaInP semiconductor layer, and an n-AlInP semiconductor layer, which are doped with n-type impurities. For example, the first semiconductor layer SEM1 may include an n-GaInP semiconductor layer, an n-AlGaInP semiconductor layer, and an n-AlInP semiconductor layer sequentially disposed on the substrate SUB. The material and/or structure of the first semiconductor layer SEM1 may be altered in a variety of ways.

The active layer EML and the passivation layer PSV may be disposed on the first semiconductor layer SEM1. The active layer EML may be disposed on the first semiconductor layer SEM1 such that it is surrounded by the passivation layer PSV. According to an embodiment, the passivation layer PSV may be a semiconductor layer including a semiconductor material (also referred to as a third semiconductor layer). According to an embodiment, an additional semiconductor layer may be disposed around the active layer EML and the passivation layer PSV. For example, an etch stop layer EST including a semiconductor material (also referred to as a fourth semiconductor layer) may be disposed around the active layer EML and the passivation layer PSV.

The active layer EML may be disposed between the first semiconductor layer SEM1 and the second semiconductor layer SEM2. The active layer EML may emit light as electron-hole pairs are recombined therein in response to an electrical signal applied through the first semiconductor layer SEM1 and the second semiconductor layer SEM2. For example, the active layer EML may be an emissive layer of the light-emitting element LE.

According to an embodiment, the active layer EML may be an emissive layer having a multiple quantum well (MQW) structure. For example, as shown in FIG. 2, the active layer EML may have a multiple quantum well (MQW) structure in which quantum well layers QWL and barrier layers QBR are alternately stacked each other. The active layer EML may include other Group III to Group V semiconductor materials according to the wavelength band of emitted light.

According to an embodiment the active layer EML may be formed of an inorganic material such as a phosphide semiconductor material and a nitride semiconductor material. For example, the active layer EML may include phosphide semiconductor materials such as GaP, GaInP, AlGaP, AlInP, AlGaInP, AlP and InP; nitride semiconductor materials such as GaN, AlGaN, InGaN, AlInGaN, AlN and InN; or other inorganic materials.

According to an embodiment, the active layer EML may include a phosphide semiconductor material and may emit red light. For example, a quantum well layer QWL of the active layer EML may be formed of GaInP, and a barrier layer QBR may be formed of AlGaInP.

The passivation layer PSV (also referred to as passivation film) may cover surfaces of the active layer EML including a side surface (or side surfaces). For example, the passivation layer PSV may entirely cover the surfaces of the active layer EML including a first bottom surface (for example, the bottom surface), a second bottom surface (for example, the top surface), and the side surface of the active layer EML. According to an embodiment, the passivation layer PSV may include a first passivation layer PSV1, a second passivation layer PSV2, a third passivation layer PSV3 and a fourth passivation layer PSV1 forming different portions of the passivation layer PSV.

The first passivation layer PSV1 may be disposed between the first semiconductor layer SEM1 and the active layer EML. The first passivation layer PSV1 may be a first portion of the passivation layer PSV covering the first semiconductor layer SEM1.

The second passivation layer PSV2 may be disposed at a peripheral region of the first passivation layer PSV1 that does not overlap the active layer EML. The second passivation layer PSV2 may be a second portion of the passivation layer PSV that surrounds the side surface of the active layer EML.

The third passivation layer PSV3 may be disposed at a central region (for example, a region overlapping the active layer EML) of the first passivation layer PSV1. The third passivation layer PSV3 may be a third portion of the passivation layer PSV that surrounds the first bottom surface of the active layer EML.

The fourth passivation layer PSV4 may be disposed on the active layer EML. The fourth passivation layer PSV4 may be a fourth portion of the passivation layer PSV surrounding the second bottom surface of the active layer EML.

The passivation layer PSV may be in contact with the surfaces of the active layer EML. For example, the second passivation layer PSV2, the third passivation layer PSV3 and the fourth passivation layer PSV4 may be in contact with the side surface of the active layer EML, the first bottom side of the active layer EML, and the second bottom surface of the active layer EML, respectively.

The passivation layer PSV may include a semiconductor material that can suppress a decrease in efficiency due to surface defects of the active layer EML. For example, the passivation layer PSV may be formed of a semiconductor material that has a lattice that matches or identical to a lattice of the semiconductor material included in the active layer EML and has a higher band gap energy. According to an embodiment, the passivation layer PSV may include at least one semiconductor material included in the active layer EML (for example, a semiconductor compound forming the quantum well layer QWL and the barrier layer QBR of FIG. 2), and may include a semiconductor material that has a higher band gap energy than the band gap energy of the semiconductor material included in the active layer EML.

According to an embodiment, the active layer EML may have a multi-quantum well structure including the quantum well layer QWL containing GaInP and the barrier layer QBR containing AlGaInP. The passivation layer PSV may be formed of a semiconductor layer containing AlInP or may include a semiconductor layer containing AlInP. For example, the passivation layer PSV may be formed as an intrinsic semiconductor layer (for example, an i-AlInP layer) containing AlInP and fabricated without doping.

The etch stop layer EST may be disposed between the first passivation layer PSV1 and the second passivation layer PSV2. The etch stop layer EST may be disposed to surround the third passivation layer PSV2.

The etch stop layer EST may be disposed under (or below) the active layer EML but not overlap the active layer EML. For example, the etch stop layer EST may be disposed on a portion (for example, an edge) of the first passivation layer PSV1 that does not overlap the active layer EML, and may include an opening in line with active layer EML. The third passivation layer PSV3 may be disposed in the opening of the etch stop layer EST. For example, the third passivation layer PSV3 may be disposed higher than the etch stop layer EST and may be in contact with the first bottom surface of the active layer EML.

The etch stop layer EST may include a material that can act as an etch stop layer so that a surface on which the third passivation layer PSV3 or the like is to be re-grown can be formed neatly during the process of fabricating the light-emitting element LE. For example, the etch stop layer EST may include a semiconductor material that can act as an appropriate etch stop layer during a process of etching the passivation layer PSV. According to an embodiment, the etch stop layer EST may include an intrinsic semiconductor made of AlGaAs and fabricated without doping. For example, the etch stop layer EST may be formed as an intrinsic semiconductor layer (for example, an i-AlInP layer) containing AlInP and fabricated without doping.

The second semiconductor layer SEM2 and the insulating layer INS may be disposed on the passivation layer PSV.

The second semiconductor layer SEM2 may be disposed on the active layer EML and the passivation layer PSV. For example, the second semiconductor layer SEM2 may be disposed on the fourth passivation layer PSV such that it overlaps the active layer EML.

The second semiconductor layer SEM2 may be formed of an inorganic material such as a phosphide semiconductor material and a nitride semiconductor material. For example, the second semiconductor layer SEM2 may include phosphide-based semiconductor materials such as GaP, GaInP, AlGaP, AlInP, AlGaInP, AlP and InP; nitride-based semiconductor materials such as GaN, AlGaN, InGaN, AlInGaN, AlN and InN; or other inorganic materials.

The second semiconductor layer SEM2 may be doped to a second conductivity type. For example, the second semiconductor layer SEM2 may include a semiconductor material doped with a second conductivity type dopant. According to an embodiment, the second semiconductor layer SEM2 may be a p-type semiconductor layer with a p-type dopant (for example, Mg, Zn, Ca, Sc, Ba, or other p-type dopants) used in forming a p-type semiconductor.

According to an embodiment, the second semiconductor layer SEM2 may be a single-layer or multi-layer semiconductor layer including at least one of: a p-AlInP semiconductor layer, a p-AlGaInP semiconductor layer, and a p-GaP semiconductor layer, which are doped with p-type impurities. For example, the second semiconductor layer SEM2 may include a p-AlInP semiconductor layer, a p-AlGaInP semiconductor layer and a p-GaP semiconductor layer sequentially disposed on the passivation layer PSV. The material and/or structure of the second semiconductor layer SEM2 may be altered in a variety of ways.

The insulating layer INS may be disposed on a portion of the passivation layer PSV, for example, a peripheral region of the passivation layer PSV that does not overlap the active layer EML. The insulating layer INS may cover the peripheral region of the passivation layer PSV and at least partially cover a side surface (or side surfaces) of the second semiconductor layer SEM2. Electrical stability of the light-emitting element LE can be improved by the insulating layer INS.

The insulating layer INS may include at least one insulating material selected from silicon oxide (SiOₓ) (for example, SiO₂), silicon nitride (SiNₓ) (for example, Si₃N₄), aluminum oxide (AlₓO_{y}) (for example, Al₂O₃), titanium oxide (TiₓO_{y}) (for example, TiO₂) and hafnium oxide (HfOₓ), or other insulating materials. The insulating layer INS may be made up of a single layer or multiple layers. It should be noted that the material and/or structure of the insulating layer INS is not particularly limited but may be altered according to embodiments.

A contact electrode CTE may be disposed at one end or an end of the light-emitting element LE on which the second semiconductor layer SEM2 is disposed. For example, the contact electrode CTE may be disposed and/or formed on the second semiconductor layer SEM2.

The contact electrode CTE may protect the second semiconductor layer SEM2 and smoothly connect the second semiconductor layer SEM2 to at least one circuit element, electrode, and/or line. The contact electrode CTE may include metal, metal oxide, or other conductive material.

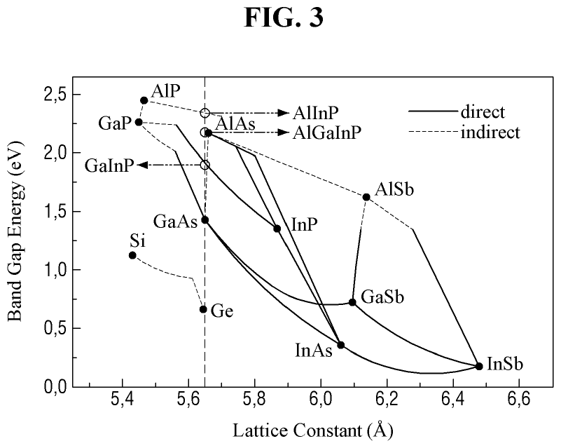

FIG. 3 is a graph showing band gap energy versus lattice constant of example semiconductor materials.

Referring to FIG. 3 in conjunction with FIGS. 1 and 2, a semiconductor material forming the passivation layer PSV, for example, AlInP, may have a lattice constant identical to that of the semiconductor material forming the active layer EML, for example, GaInP and AlGaInP, and may have a higher band gap energy (for example, in a range of about 2.3 eV to about 2.4 cV) than the semiconductor material forming the active layer EML. According to an embodiment, by adjusting the ratio of elements (the ratio of aluminum (Al), indium (In) and phosphorus (P)) forming AlInP used as the material of the passivation layer PSV, it is possible to form the passivation layer PSV having a higher band gap energy than the active layer EML.

According to the embodiment described above with reference to FIGS. 1 to 3, the emission efficiency of the light-emitting element LE can be improved. For example, according to the above-described embodiment, the emission efficiency of the light-emitting element LE can be improved by suppressing surface defects of the light-emitting element LE and preventing or reducing non-emissive recombination of electrons and holes by the passivation layer PSV.

For example, according to the embodiment, the surfaces of the active layer EML may be surrounded by the passivation layer PSV including the semiconductor material (for example, a semiconductor compound such as i-AlInP) that has the lattice that matches or is identical to that of the semiconductor material (for example, a semiconductor compound such as GaInP and AlGaInP) contained in the active layer EML. Accordingly, it is possible to suppress surface defects of the light-emitting element LE. By forming the passivation layer PSV with the semiconductor material having a higher band gap energy than the semiconductor material contained in the active layer EML, recombination of electrons and holes in the quantum well layer QWL may be induced. In this manner, it is possible to prevent or reduce electrons and holes from recombining without emitting light, for example, non-emissive recombination. For example, the ratio of volume to surface area may increase as the size of the light-emitting element LE decreases. Accordingly, by disposing the passivation layer PSV having a band gap energy higher than that of the active layer EML on the surfaces of the active layer EML, it is possible to prevent, suppress or reduce non-emissive recombination of electrons and holes. In this manner, it is possible to prevent or reduce a decrease in the emission efficiency as the size of the light-emitting element LE decreases.

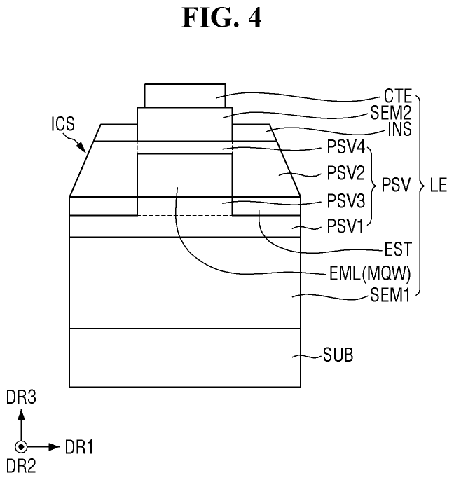

FIG. 4 is a schematic cross-sectional view showing a light-emitting element LE according to an embodiment. In the following description, the same reference numerals are assigned to elements similar or identical to those of the above-described embodiments, and redundant descriptions will be omitted.

Referring to FIG. 4 in conjunction with FIGS. 1 to 3, the light-emitting element LE may have an inclined surface (or inclined surfaces) ICS at least partially. For example, the passivation layer PSV (for example, the second passivation layer PSV) and the insulating layer INS of the light-emitting element LE may be etched at an appropriate angle to have the side surface including the inclined surface ICS.

According to an embodiment, the second passivation layer PSV and the insulating layer INS may have a trapezoidal cross-sectional shape in which the lower surface is wider than the upper surface. According to an embodiment, the second passivation layer PSV and the insulating layer INS may have an inverted trapezoidal cross-sectional shape in which the upper surface is wider than the lower surface. The shape of the light-emitting element LE may be variously modified according to different embodiments.

In a device using the light-emitting element LE as a light source (for example, a display device or a luminaire), the position, direction and/or angle of the inclined surface ICS formed in the light-emitting element LE may be appropriately adjusted taking into count the direction in which the light-emitting element LE is disposed or the emission efficiency, etc. Accordingly, the emission efficiency of the light-emitting element LE can be increased.

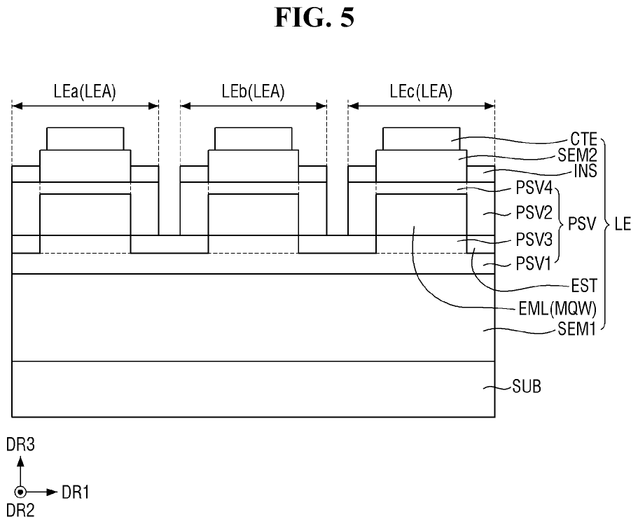

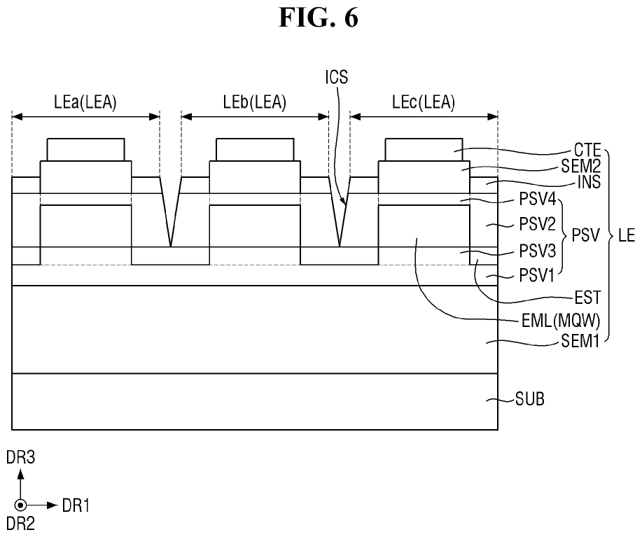

FIG. 5 is a schematic cross-sectional view showing a light-emitting element LE according to an embodiment. FIG. 6 is a schematic cross-sectional view showing a light-emitting element LE according to an embodiment. For example, FIGS. 5 and 6 show different shapes of passivation layers PSV and insulating layers INS according to different embodiments.

Referring to FIGS. 5 and 6 in conjunction with FIGS. 1 to 4, the light-emitting element LE may include subsidiary light-emitting elements LEa, LEb and LEc partially connected with one another and located (or disposed) in light-emitting areas LEA (or subsidiary areas). Although a light-emitting element LE may include three subsidiary light-emitting elements LEa, LEb and LEc arranged (or disposed) in the first direction DR1 according to the embodiments of FIGS. 5 and 6, the number and/or arrangement structure of the subsidiary light-emitting elements LEa, LEb and LEc may be altered in a variety of ways.

The subsidiary light-emitting elements LEa, LEb and LEc may have portions connected to each other, including the first semiconductor layer SEM1, and may share the portions. For example, the subsidiary light-emitting elements LEa, LEb and LEc may be fabricated such that elements disposed below the etch stop layer EST are connected to one another. For example, the subsidiary light-emitting elements LEa, LEb and LEc may share the first semiconductor layer SEM1 and may include the individually separated active layers EML and the respective second semiconductor layers SEM2.

The subsidiary light-emitting elements LEa, LEb and LEc may have a configuration and/or structure substantially similar to that of each light-emitting element LE according to the embodiments described above with reference to FIGS. 1 to 4. Accordingly, the configurations of the subsidiary light-emitting elements LEa, LEb, and LEc will not be described in detail.

According to an embodiment, as shown in FIG. 5, the subsidiary light-emitting elements LEa, LEb and LEc may include substantially vertical side surfaces where they are separated from each other. According to an embodiment, as shown in FIG. 6, the subsidiary light-emitting elements LEa, LEb and LEc may include inclined side surfaces having inclined surfaces ICS where they are separated from each other. For example, the light-emitting element LE may have inclined surfaces ICS between the subsidiary light-emitting elements LEa, LEb and LEc, and the emission efficiency of the light-emitting element LE can be adjusted or improved by adjusting the angle at which the inclined surfaces ICS is formed.

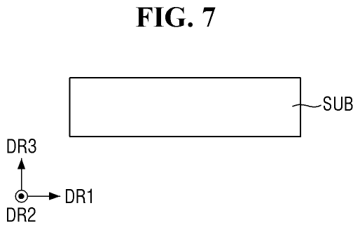

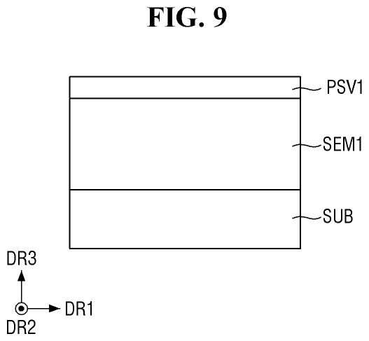

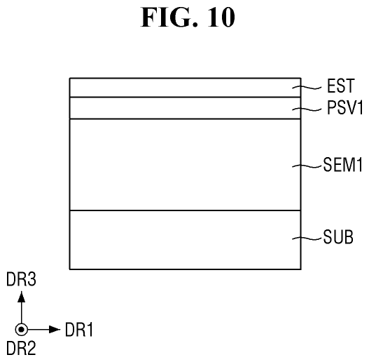

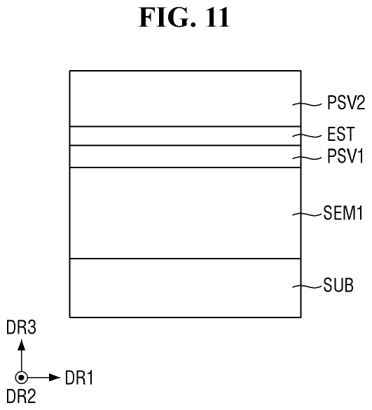

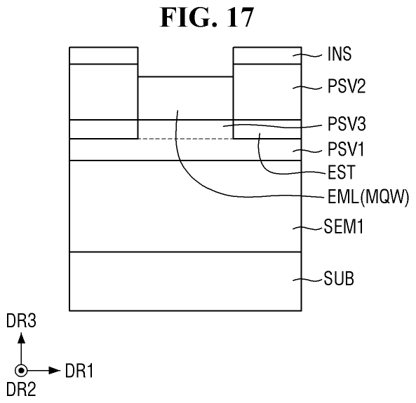

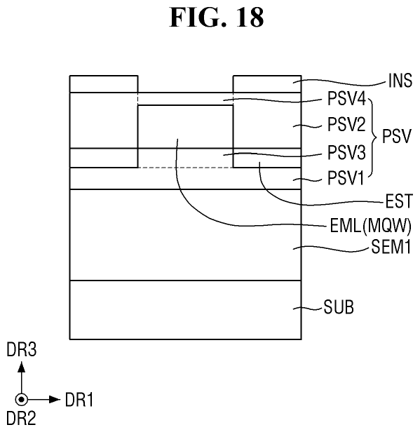

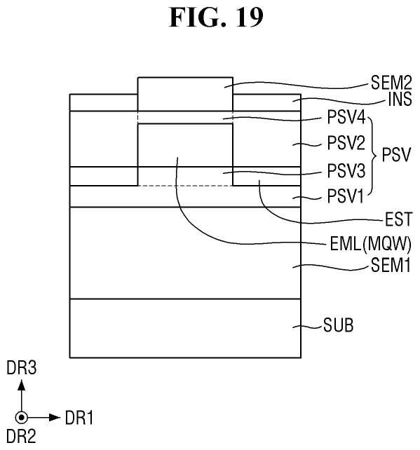

FIGS. 7 to 19 are schematic cross-sectional views showing a method of fabricating a light-emitting element LE according to an embodiment. For example, FIGS. 7 to 19 are schematic cross-sectional views showing processing steps for fabricating the light-emitting element LE according to the embodiment of FIG. 1. The light-emitting elements LE according to the embodiments of FIGS. 4 to 6 may be fabricated by a method that is substantially identical to the method of fabricating the light-emitting element LE according to the embodiment of FIG. 1.

Referring to FIG. 7 in conjunction with FIGS. 1 to 6, first, a substrate SUB for fabricating a light-emitting element LE by epitaxial growth may be prepared. According to an embodiment, the substrate SUB may be a semiconductor substrate suitable for epitaxial growth of semiconductor. For example, the substrate SUB may be a semiconductor substrate made of GaAs.

According to an embodiment, a buffer layer (not shown) may be first formed on the substrate SUB. The buffer layer may be formed as at least one semiconductor layer including a semiconductor layer not doped with impurities.

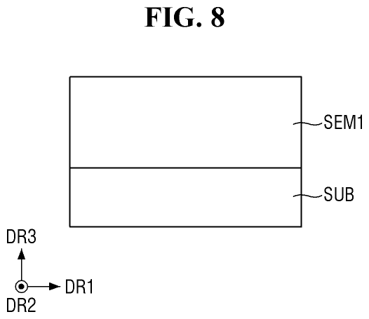

Referring to FIGS. 8 to 11 in conjunction with FIGS. 1 to 7, on the substrate SUB (or the buffer layer formed on the substrate SUB), a first semiconductor layer SEM1, a first passivation layer PSV1, an etch stop layer EST, and a second passivation layer PSV2 may be formed sequentially. For example, a first semiconductor layer SEM1, a first passivation layer PSV1, an etch stop layer EST, and a second passivation layer PSV2 may be sequentially formed on the substrate SUB by epitaxial growth.

The first semiconductor layer SEM1 may be formed of the materials of the first semiconductor layer SEM1 listed above. For example, the first semiconductor layer SEM1 may be formed of at least one of GaInP, AlGaInP and AlInP, and may be formed as a single layer or multi-layer semiconductor layer. The first semiconductor layer SEM1 may be doped to include a first conductivity-type dopant (for example, an n-type dopant).

The first passivation layer PSV1 may be formed using the materials of the passivation layer PSV listed above. For example, the first passivation layer PSV1 may be formed of a semiconductor material that has a lattice that matches or is identical to that of the semiconductor material included in the active layer EML and has a band gap energy higher than that of the semiconductor material, for example, AlInP, and may not be doped.

The etch stop layer EST may be formed using the materials of the etch stop layer EST listed above. For example, the etch stop layer EST may be formed of AlGaAs and may not be doped.

The second passivation layer PSV2 may be formed using the materials of the passivation layer PSV listed above. For example, the second passivation layer PSV2 may be formed of a semiconductor material that has a lattice that matches or is identical to that of the semiconductor material included in the active layer EML and has a band gap energy higher than that of the semiconductor material, for example, AlInP, and may not be doped.

The first semiconductor layer SEM1, the first passivation layer PSV1, the etch stop layer EST and the second passivation layer PSV2 may be formed by epitaxial growth utilizing process technologies such as metal-organic chemical vapor deposition (MOCVD), metal-organic vapor phase epitaxy (MOVPE), molecular beam epitaxy (MBE), liquid phase epitaxy (LPE), and vapor phase epitaxy (VPE). According to an embodiment, the first semiconductor layer SEM1, the first passivation layer PSV1, the etch stop layer EST and the second passivation layer PSV2 may be formed by, but is not limited to, epitaxial growth using MOCVD technology. Through the above-described processes, it is possible to prepare the semiconductor substrate for re-growing the active layer EML or the like within the spirit and the scope of the disclosure.

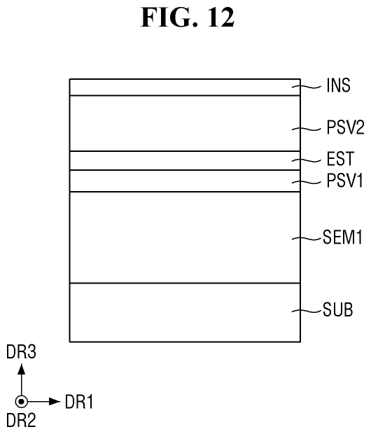

Referring to FIGS. 12 to 15 in conjunction with FIGS. 1 to 11, after the insulating layer INS is formed on the second passivation layer PSV2, the insulating layer INS, the second passivation layer PSV2 and the etch stop layer EST may be sequentially patterned so that a part of the first passivation layer PSV1 is exposed, which corresponds to the region where the active layer EML and the like are to be formed (for example, a region having a selectable shape and/or area including a center of the region where the light-emitting element LE is to be formed).

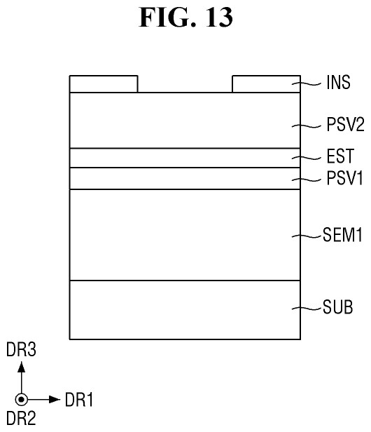

For example, after the insulating layer INS is formed over the substrate SUB on which the second passivation layer PSV2 and the like have been formed as shown in FIG. 12, the insulating layer INS may be partially etched so that a part of the second passivation layer PSV2 (for example, a part that the center of the region where the light-emitting element LE is to be formed) is exposed, as shown in FIG. 13. The insulating layer INS may be formed using the materials of the insulating layer INS listed above. The insulating layer INS may be formed by a deposition technique using the process technologies such as ALD and CVD, but the method of forming the insulating layer INS is not limited thereto. Accordingly, the insulating layer INS may be patterned via an etching process to have an opening with a location and size corresponding to a region where the emissive layer EML is to be formed.

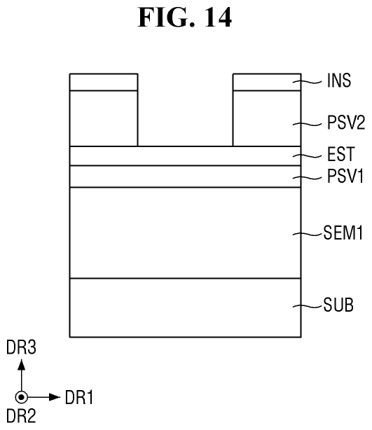

Subsequently, as shown in FIG. 14, a part of the second passivation layer PSV2 exposed by the opening of the insulating layer INS may be etched out. As a result, the second passivation layer PSV2 may be patterned to have an opening with a location and size corresponding to the region where the emissive layer EML is to be formed. According to an embodiment, the second passivation layer PSV2 may be patterned via a dry etching process, but the method of patterning the second passivation layer PSV2 is not limited thereto. A part of the etch stop layer EST may be exposed by the opening of the second passivation layer PSV2.

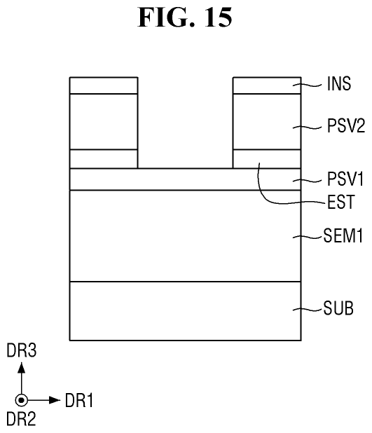

Subsequently, as shown in FIG. 15, the exposed part of the etch stop layer EST may be etched out. Accordingly, the etch stop layer EST may be patterned to have an opening with a location and size corresponding to the region where the emissive layer EML is to be formed. According to an embodiment, the etch stop layer EST may be patterned via etching processes including a wet etching process, but the method of patterning the etch stop layer EST is not limited thereto. A part of the first passivation layer PSV1 (for example, a region corresponding to the region where the emissive layer EML is to be formed) may be exposed by the opening of the etch stop layer EST.

Through the above-described processes, it is possible to prepare the pattern substrate on which an active area is defined where the emissive layer EML and the like are to be formed.

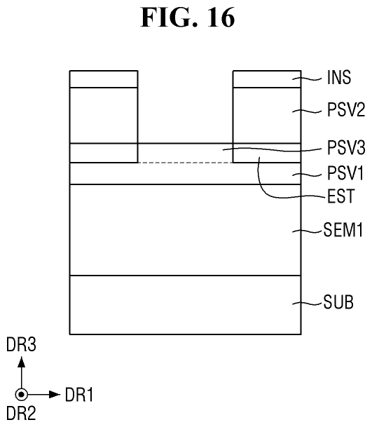

Referring to FIGS. 16 to 19 in conjunction with FIGS. 1 to 15, a third passivation layer PSV3, an active layer EML, a fourth protective layer PSV4 and a second semiconductor layer SEM2 may be sequentially formed on the pattern substrate where a part of the first passivation layer PSV1 is exposed. For example, on the exposed part of the first passivation layer PSV1, the third passivation layer PSV3, the active layer EML, the fourth passivation layer PSV4 and the second semiconductor layer SEM2 may be formed sequentially by epitaxial regrowth.

The third passivation layer PSV3 may be formed using the materials of the passivation layer PSV listed above. For example, the third passivation layer PSV3 may be formed of a semiconductor material that has a lattice that matches or is identical to that of the semiconductor material included in the active layer EML and has a band gap energy higher than that of the semiconductor material, for example, AlInP, and may not be doped.

The active layer EML may be formed using the materials of the active layer EML listed above. For example, the active layer EML having a multi-quantum well structure may be formed by alternately forming a barrier layer QBR containing AlGaInP and a quantum well layer QWL containing GaInP on the third passivation layer PSV3.

The fourth passivation layer PSV4 may be formed using the materials of the passivation layer PSV listed above. For example, the fourth passivation layer PSV4 may be formed of a semiconductor material that has a lattice that matches or is identical to that of the semiconductor material included in the active layer EML and has a band gap energy higher than that of the semiconductor material, for example, AlInP, and may not be doped. According to an embodiment, the first passivation layer PSV1, the second passivation layer PSV2, the third passivation layer PSV3 and the fourth passivation layer PSV4 may be formed of the same material and may be regarded as different portions forming the single passivation layer PSV.

The second semiconductor layer SEM2 may be formed of the materials of the second semiconductor layer SEM2 listed above. For example, the second semiconductor layer SEM2 may be formed of at least one of AlInP, AlGaInP and GaP, and may be formed as a single layer or multi-layer semiconductor layer. The second semiconductor layer SEM2 may be doped to include a second conductivity-type dopant (for example, a p-type dopant).

The third passivation layer PSV3, the active layer EML, the fourth passivation layer PSV4 and the second semiconductor layer SEM2 may be formed by epitaxial regrowth (or epitaxial growth) using the process technologies such as MOCVD, MOVPE, MBE, LPE and VPE. According to an embodiment, the third passivation layer PSV3, the active layer EML, the fourth passivation layer PSV4 and the second semiconductor layer SEM2 may be formed by, but is not limited to, epitaxial regrowth using MOCVD technology.

According to an embodiment where the light-emitting element LE including the contact electrode CTE is fabricated as in the embodiment of FIG. 1, a process of forming the contact electrode CTE on the second semiconductor layer SEM2 may be performed additionally. According to an embodiment where the light-emitting element LE is separated from the substrate SUB, a process of separating the light-emitting element LE from the substrate SUB may be performed additionally.

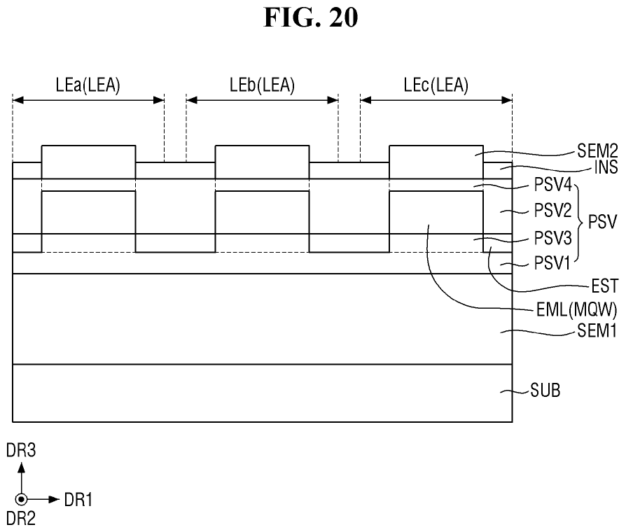

FIGS. 20 to 24 are schematic cross-sectional views showing a method of fabricating a light-emitting element LE according to an embodiment. For example, FIGS. 20 to 24 are schematic cross-sectional views showing a method of fabricating the light-emitting elements LE according to the embodiments of FIGS. 5 and 6.

Referring to FIG. 20 in conjunction with FIGS. 1 to 19, subsidiary light-emitting elements LEa, LEb and LEc may be formed in the light-emitting areas LEA, respectively. For example, on the substrate SUB including the light-emitting element areas LEA, a first semiconductor layer SEM1, a passivation layer PSV, an etch stop layer EST, an insulating layer INS, an active layer EML and a second semiconductor layer SEM2 may be formed. The method of forming the first semiconductor layer SEM1, the passivation layer PSV, the etch stop layer EST, the insulating layer INS, the active layer EML and the second semiconductor layer SEM2 may be substantially identical to that in the embodiment of FIGS. 7 to 19.

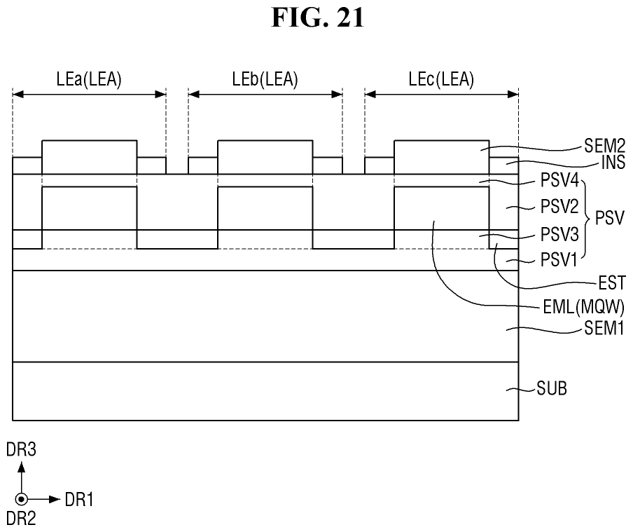

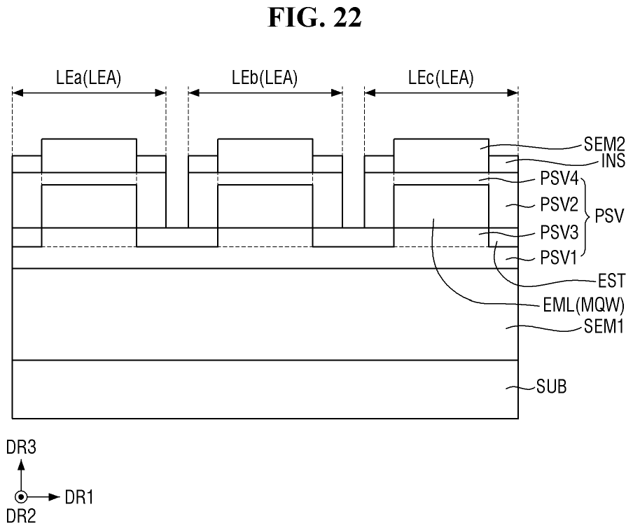

Referring to FIGS. 21 and 22 in conjunction with to FIGS. 1 to 20, the insulating layer INS and a part of the passivation layer PSV (for example, the second passivation layer PSV2) between the light-emitting areas LEA may be sequentially etched out. Accordingly, the insulating layer INS and the part of the passivation layer PSV (for example, the second passivation layer PSV2) of the subsidiary light-emitting elements LEa, LEb and LEc may be separated from one another. For example, the light-emitting element LE according to the embodiment of FIG. 5 may be fabricated by vertically etching the insulating layer INS and the second passivation layer PSV2 between the light-emitting areas LEA.

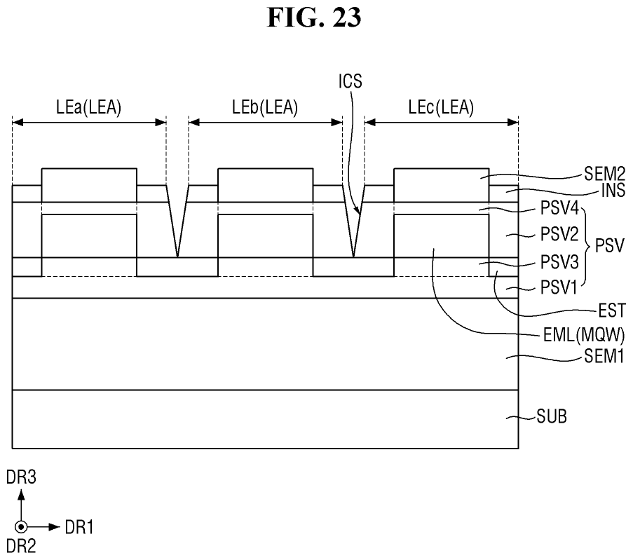

Referring to FIG. 23 in conjunction with FIGS. 1 to 22, in the step of etching the insulating layer INS and/or the passivation layer PSV, the insulating layer INS and/or the passivation layer PSV may be etched to have the inclined surfaces ICS at a selectable angle or range, so that the light-emitting element LE including the inclined surfaces ICS can be fabricated. For example, the angle of the inclined surfaces ICS formed on the side surfaces of the second passivation layer PSV2 may be adjusted by adjusting the angle at which the second passivation layer PSV2 is etched between the light-emitting areas LEA. According to an embodiment, the angle or range at which the inclined surfaces ICS are formed may be adjusted take into account the emission efficiency of the light-emitting element LE.

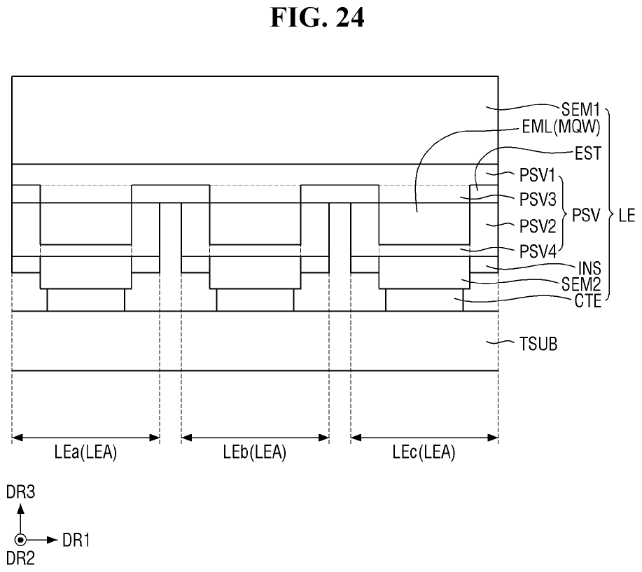

Referring to FIG. 24 in conjunction with FIGS. 1 to 23, to fabricate the light-emitting element LE including the contact electrode CTE, a process of forming the contact electrode CTE on the second semiconductor layer SEM2 may be performed additionally. For example, the contact electrode CTE may be formed on the second semiconductor layer SEM2. To fabricate the light-emitting element LE separated from the substrate SUB, one end or an end of the light-emitting element LE at which the contact electrode CTE is formed may be placed on a transfer substrate TSUB (or transport substrate), and the substrate SUB may be separated from the light-emitting element LE. According to an embodiment, the substrate SUB may be separated from the light-emitting element LE by electrical and/or chemical etching, laser lift-off, or other techniques.

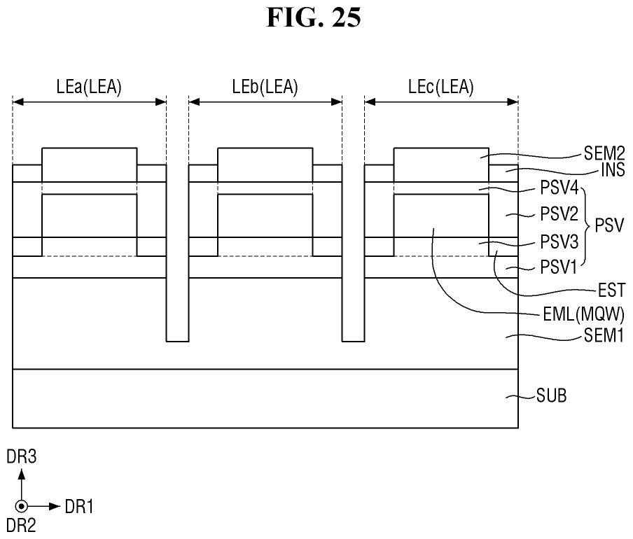

FIGS. 25 to 27 are schematic cross-sectional views showing a method of fabricating light-emitting elements LE according to embodiments. For example, FIGS. 25 to 27 show different embodiments where subsidiary light-emitting elements LEa, LEb and LEc and/or light-emitting elements LE are fabricated on a single substrate SUB, in terms of separation of the subsidiary light-emitting elements LEa, LEb and LEc or the light-emitting elements LE.

Referring to FIG. 25 in conjunction with FIGS. 1 to 24, subsidiary light-emitting elements LEa, LEb and LEc formed in the light-emitting areas LEA, respectively, may be separated from one another at least partially. For example, after the second semiconductor layer SEM2 has been formed, a part of the first semiconductor layer SEM1 (for example, an upper part above a selectable height), the passivation layer PSV, the etch stop layer EST and the insulating layer INS may be etched so that the subsidiary light-emitting elements LEa, LEb and LEc share only a part of the first semiconductor layer SEM1 (for example, a lower part). In this manner, the subsidiary light-emitting elements LEa, LEb and LEc may be separated from one another above a given height of the first semiconductor layer SEM1. The light-emitting areas LEA may be arranged with shapes, sizes and/or spacing corresponding to the respective subsidiary light-emitting elements LEa, LEb and LEc. According to an embodiment, a process of forming a contact electrode CTE in each of the light-emitting areas LEA may be added.

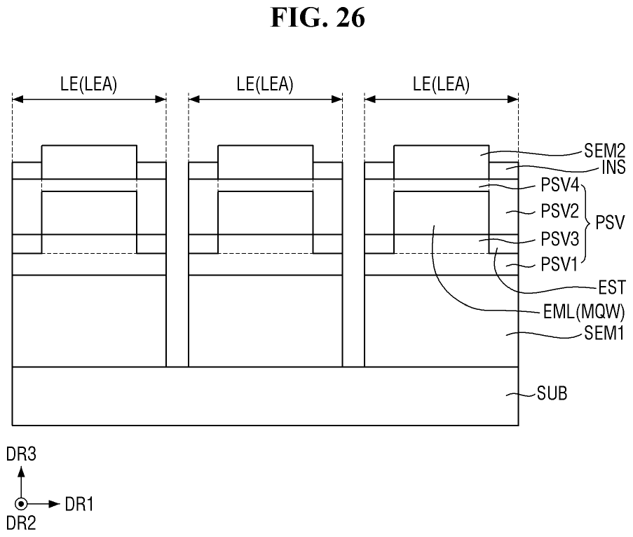

Referring to FIG. 26 in conjunction with FIGS. 1 to 25, light-emitting elements LE may be separated from one another such that they are formed in the light-emitting areas LEA, respectively. For example, after the second semiconductor layer SEM2 is formed, the first semiconductor layer SEM1, the passivation layer PSV, the etch stop layer EST and the insulating layer INS between the light-emitting areas LEA are completely etched to the overall thickness, to form the light-emitting elements LE. The light-emitting areas LEA may be arranged with shapes, sizes and/or spacing corresponding to the respective light-emitting elements LE. Light-emitting elements LE may be simultaneously fabricated on one substrate SUB by the above-described manner. According to an embodiment, a process of forming a contact electrode CTE in each of the light-emitting areas LEA may be added.

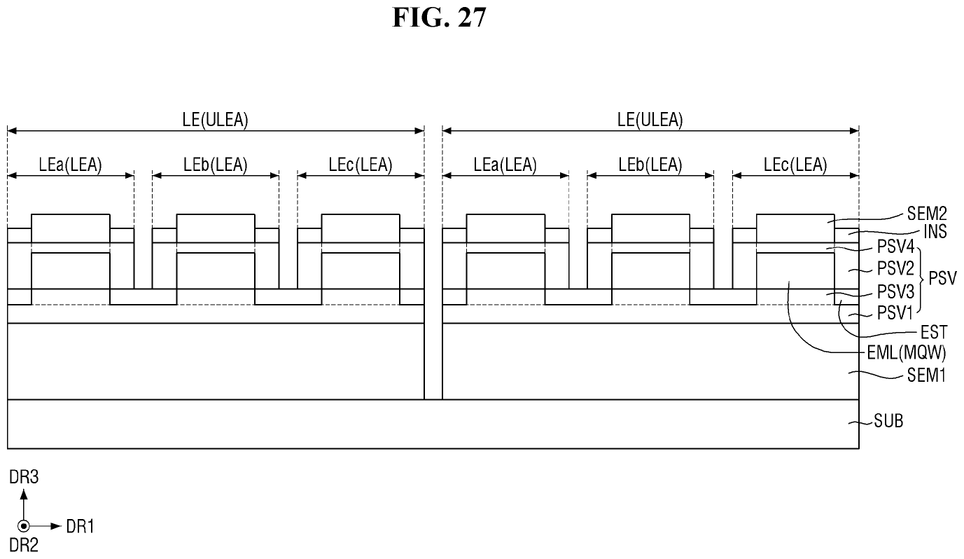

Referring to FIG. 27 in addition to FIGS. 1 to 26, a light-emitting element LE including at least two subsidiary light-emitting elements LEa, LEb and LEc may be formed in each of unit areas ULEA including at least two light-emitting areas LEA. For example, light-emitting elements LE each including at least two subsidiary light-emitting elements LEa, LEb and LEc may be fabricated simultaneously on a single substrate SUB including light-emitting areas LEA. According to an embodiment, the subsidiary light-emitting elements LEa, LEb and LEc may be formed such that they are connected with one another including at least a part of the first semiconductor layer SEM1, and the light-emitting elements LE may be formed on the substrate SUB such that they are separated or spaced apart from each other. The light-emitting areas LEA may be arranged with shapes, sizes and/or spacing corresponding to the respective subsidiary light-emitting elements LEa, LEb and LEc and the respective light-emitting elements LE. According to an embodiment, a process of forming a contact electrode CTE in each of the light-emitting areas LEA may be added.

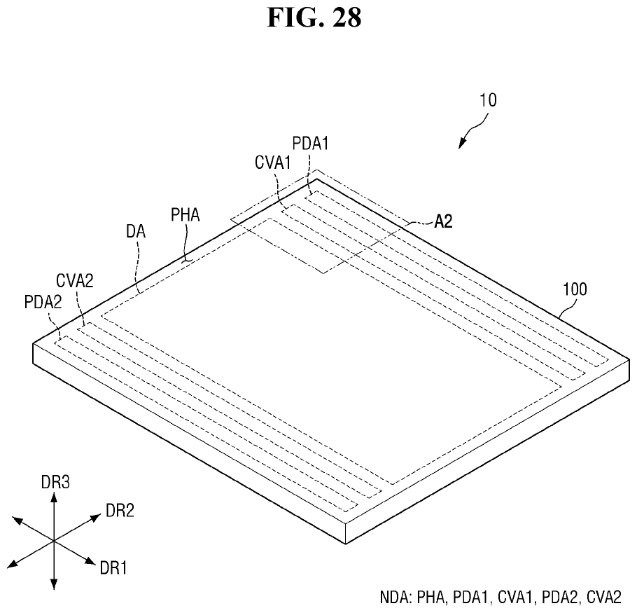

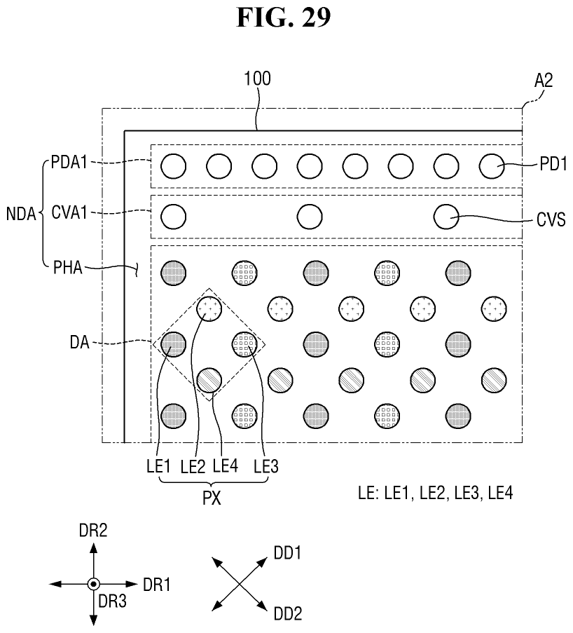

FIG. 28 is a schematic perspective view showing a display device 10 according to an embodiment. FIG. 29 is a schematic plan view showing an example of area A2 of FIG. 28.

In the example shown in FIGS. 28 and 29, the display device 10 according to the embodiment is implemented as a light-emitting diode on silicon (LEDoS) display, in which light-emitting diodes are disposed on a semiconductor circuit substrate 101 formed via a semiconductor process using a silicon wafer as light-emitting elements LE. It should be understood, however, that the devices including the light-emitting element according to the embodiments are not limited thereto. For example, the light-emitting elements LE according to the embodiments may be applied to a display device of a different type and/or structure from LEDoS, or may be applied to a device of a different type and/or structure, such as a luminaire.

In FIGS. 28 and 29, the first direction DR1 may indicate the horizontal direction of the display panel 100, the second direction DR2 may indicate the vertical direction of the display panel 100, and the third direction DR3 may indicate the thickness direction of the display panel 100 (or the semiconductor circuit substrate). As used herein, the terms “left,” “right,” “upper” and “lower” sides may indicate relative positions in case that the display panel 100 is viewed from the top. For example, the right side may refer to one side or a side in the first direction DR1, the left side may refer to the other side in the first direction DR1, the upper side may refer to one side or a side in the second direction DR2, and the lower side may refer to the other side or another side in the second direction DR2. The upper portion may refer to the side indicated by the arrow of the third direction DR3, while the lower portion may refer to the opposite side in the third direction DR3.

Referring to FIGS. 28 to 29, a display device 10 according to an embodiment may include a display panel 100 including a display area DA and a non-display area NDA.

The display panel 100 may have a rectangular shape having longer sides in the first direction DR1 and shorter sides in the second direction DR2 when viewed from the top. It should be understood, however, that the shape of the display panels 100 when viewed from the top is not limited thereto. It may have a polygonal shape other than the rectangular shape, a circular shape, an elliptical shape or irregular shapes when viewed from the top.

In the display area DPA, images can be displayed. In the non-display area NDA, images may not be displayed. According to an embodiment, the shape of the display area DA may follow the shape of the display panel 100 when viewed from the top. In the example shown in FIG. 28, the display area DA has a rectangular shape when viewed from the top. The display area DA may be disposed at the central area of the display panel 100. The non-display area NDA may be disposed around the display area DA. For example, the non-display area NDA may surround or may be adjacent to the display area DA.

The display area DA of the display panel 100 may include pixels PX. The pixels PX may include light-emitting elements LE. Each of the pixels PX may be defined as a minimum light-emitting unit capable of displaying white light by combining lights emitted from the light-emitting elements LE.

Each of the pixels PX may include first to fourth light-emitting elements LE1, LE2, LE3 and LE4.

The first light-emitting elements LE1 may emit first light. The first light may be red light. For example, the main peak wavelength R-peak of the first light may be in a range of about 600 nm to about 750 nm, but embodiments of the disclosure are not limited thereto.

The second light-emitting element LE2 and the fourth light-emitting element LE4 may emit second light. The second light may be green light. For example, the main peak wavelength G-peak of the second light may be in a range of about 480 nm to about 560 nm, but embodiments are not limited thereto.

The third light-emitting element LE3 may emit third light. The third light may be blue light. For example, the main peak wavelength B-peak of the third light may be in a range of about from 370 nm to about 460 nm, but embodiments are not limited thereto.

In the display area DA, the first light-emitting elements LE1 and the third light-emitting elements LE3 may be arranged alternately in the first direction DR1 and in the second direction DR2. In the display area DA, the second light-emitting elements LE2 and the fourth light-emitting elements LE4 may be arranged alternately in the first direction DR1 and in the second direction DR2.

In the display area DA, the first light-emitting elements LE1, the second light-emitting elements LE2, the third light-emitting elements LE3 and the fourth light-emitting elements LE4 may be arranged sequentially and repeatedly in a first diagonal direction DD1 and a second diagonal direction DD2. The first diagonal direction DD1 may be a diagonal direction between the first and second directions DR1 and DR2, and the second diagonal direction DD2 may be perpendicular to the first diagonal direction DD1.

In each of the pixels PX, the first light-emitting element LE1 and the third light-emitting element LE3 may be arranged in the first direction DR1, and the second light-emitting element LE2 and the fourth light-emitting element LE4 may be arranged in the first direction DR1. In each of the pixels PX, the first light-emitting element LE1 and the second light-emitting element LE2 may be arranged in the first diagonal direction DD1, the second light-emitting element LE2 and the third light-emitting element LE3 may be arranged in the second diagonal direction DD2, and the third light-emitting element LE3 and the fourth light-emitting element LE4 may be arranged in the first diagonal direction DD1. It should be understood, however, that the embodiments are not limited thereto. The type, number, ratio and/or arrangement structure of the light-emitting elements LE included in each of the pixels PX may be modified depending on difference embodiments.

The fourth light-emitting element LE4 may be substantially identical to the second light-emitting element LE2. For example, the fourth light-emitting element LE4 may emit the second light and may have the same structure as the second light-emitting element LE2. The second light and the fourth light may be green lights.

As shown in FIG. 29, the area of the first light-emitting element LE1, the area of the second light-emitting element LE2, the area of the third light-emitting element LE3 and the area of the fourth light-emitting element LE4 may be substantially all equal. It should be understood, however, that the embodiments are not limited thereto. As shown in FIG. 29, the distance between the first light-emitting element LE1 and the second light-emitting element LE2 adjacent to each other, the distance between the second light-emitting element LE2 and the third light-emitting element LE3 adjacent to each other, the distance between the first light-emitting element LE1 and the fourth light-emitting element LE4 adjacent to each other, and the distance between the third light-emitting element LE3 and the fourth light-emitting element LE4 adjacent to each other may be substantially all equal. It should be understood, however, that the embodiments are not limited thereto. For example, the size of each of the light-emitting elements LE and/or the spacing between the light-emitting elements LE may be modified depending on different embodiments.

Although the light-emitting elements LE may have a circular shape when viewed from the top according to the embodiment, the embodiments are not limited thereto. For example, the light-emitting elements LE may have a polygonal shape, an elliptical shape, or an atypical shape. The light-emitting elements LE may have substantially the same shape or may have different shapes for different groups when viewed from the top.

The non-display area NDA may include a first common voltage supply area CVA1, a second common voltage supply area CVA2, a first pad area PDA1, a second pad area PDA2, and a peripheral area PHA.

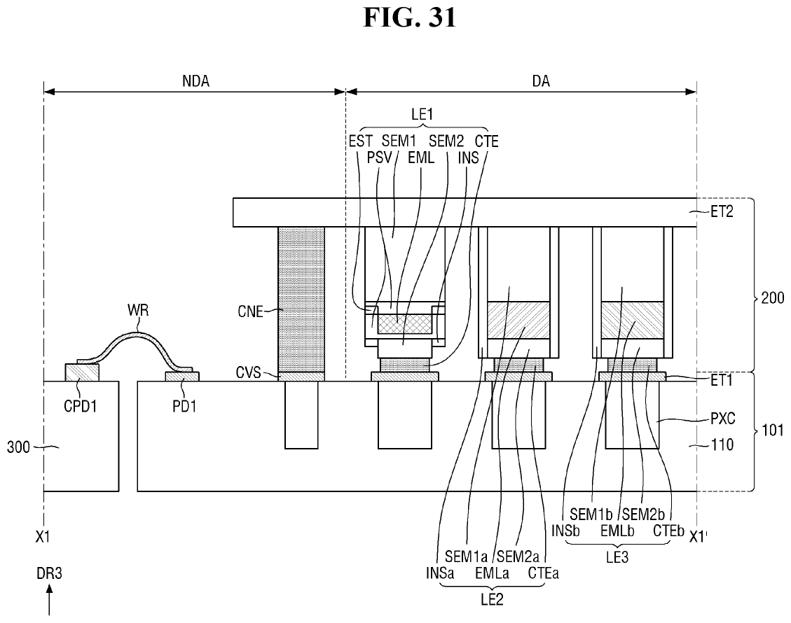

The first common voltage supply area CVA1 may be disposed between the first pad area PDA1 and the display area DA. The second common voltage supply area CVA2 may be disposed between the second pad area PDA2 and the display area DA. Each of the first common voltage supply area CVA1 and the second common voltage supply area CVA2 may include common electrode connectors CVS connected to a common electrode (for example, the second electrode ET2 of FIG. 31). The common voltage may be supplied to the common electrode through the common electrode connectors CVS.

The common electrode connectors CVS of the first common voltage supply area CVA1 may be electrically connected to one of the first pads PD1 of the first pad area PDA1. For example, the common electrode connectors CVS of the first common voltage supply area CVA1 may receive a common voltage from one of the first pads PD1 of the first pad area PDA1.

The common electrode connectors CVS of the second common voltage supply area CVA2 may be electrically connected to one of the second pads of the second pad area PDA2. For example, the common electrode connectors CVS of the second common voltage supply area CVA2 may receive a common voltage from one of the second pads of the second pad area PDA2.

The first pad area PDA1 may be disposed on one side or a side, for example, the upper side of the display panel 100. The first pad area PDA1 may include first pads PD1 connected to an external circuit board.

The second pad area PDA2 may be disposed on another side, for example, the lower side of the display panel 100. The second pad area PDA2 may include second pads connected to an external circuit board. According to an embodiment, the display panel 100 may not include the second pad area PDA2.

The peripheral area PHA may refer to the other area of the non-display area NDA than the first common voltage supply area CVA1, the second common voltage supply area CVA2, the first pad area PDA1 and the second pad area PDA2. The peripheral area PHA may surround the first common voltage supply area CVA1, the second common voltage supply area CVA2, the first pad area PDA1 and the second pad area PDA2 in addition to the display area DA.

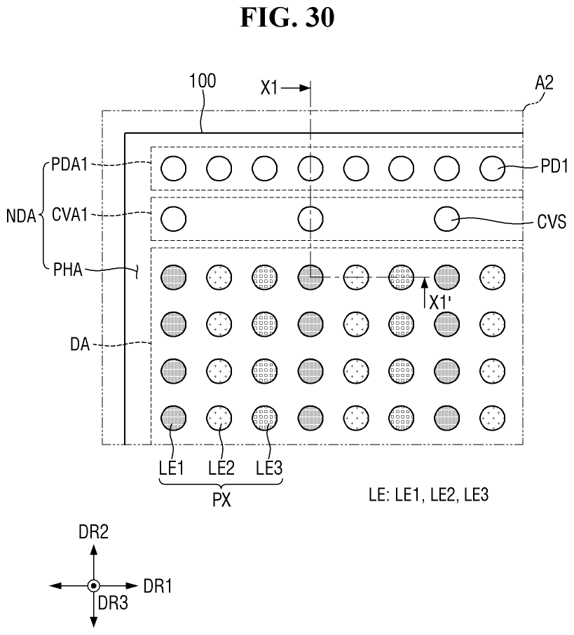

FIG. 30 is a schematic plan view showing an example of area A2 of FIG. 28. For example, FIG. 30 shows light-emitting elements LE included in each pixel PX according to an embodiment that may be different from the embodiment of FIG. 29.

Referring to FIG. 30 in conjunction with FIGS. 28 and 29, each of the pixels PX may include three light-emitting elements LE. For example, each of the pixels PX may include a first light-emitting element LE1, a second light-emitting element LE2 and a third light-emitting element LE3.

The first light-emitting elements LE1, the second light-emitting elements LE2 and the third light-emitting elements LE3 of the pixels PX may be arranged sequentially and repeatedly in the first direction DR1. For example, the first light-emitting elements LE1, the second light-emitting elements LE2 and the third light-emitting elements LE3 may be arranged in the order of the first light-emitting element LE1, the second light-emitting element and the third light-emitting element LE3 in the first direction DR1. In each of the pixels PX, the first light-emitting elements LE1, the second light-emitting elements LE2 and the third light-emitting elements LE3 may be arranged in the first direction DR1. The first light-emitting elements LE1 may be arranged in the second direction DR2. The second light-emitting elements LE2 may be arranged in the second direction DR2. The third light-emitting elements LE3 may be arranged in the second direction DR2. The arrangement structures of the first light-emitting elements LE1, the second light-emitting elements LE2 and the third light-emitting elements LE3 may be modified depending on different embodiments.

FIG. 31 is a schematic cross-sectional view showing an example of a cross section of the display panel 100, taken along line X1-X1′ of FIG. 30.

Referring to FIG. 31 in conjunction with FIGS. 1 to 30, the display panel 100 may include a semiconductor circuit substrate 101, and a light-emitting element layer 200.

The semiconductor circuit board 101 may include a first substrate 110, pixel circuits PXC, first electrodes ET1, common electrode connectors CVS, and a first pad PD1. According to an embodiment, the first electrodes ET1 may be pixel electrodes individually and/or independently connected to the pixel circuits PXC, respectively, and a second electrode ET2 may be a common electrode connected commonly to the light-emitting elements LE.

According to an embodiment, the first substrate 110 may be a silicon wafer substrate. For example, the first substrate 110 may be made of monocrystalline silicon.

Each of the pixel circuits PXC may be disposed on the first substrate 110. Each of the pixel circuits PXC may include a complementary metal-oxide semiconductor (CMOS) circuit formed using a semiconductor process. Each of the pixel circuits PXC may include at least one transistor formed via a semiconductor process. Each of the pixel circuits PXC may further include at least one capacitor formed via a semiconductor process.

The pixel circuits PXC may be disposed in the display area DA. Among the pixel circuits PXC, the pixel circuits PXC disposed in the display area DA may be electrically connected to the first electrodes ET1, respectively. For example, the pixel circuits PXC may be connected to the first electrodes ET1, respectively. The pixel circuits PXC may apply pixel voltages to the first electrodes ET1 connected thereto, respectively.

The first electrodes ET1 may be disposed in the display area DA. The first electrodes ET1 may be disposed on the respective pixel circuits PXC (also referred to as pixel driving units or pixel circuit units). Each of the first electrodes ET1 may be integral with the pixel circuit PXC and may be an electrode exposed from the pixel circuit PXC. For example, each of the first electrodes ET1 may protrude from the upper surface of the pixel circuit PXC. Each of the first electrodes ET1 may receive a pixel voltage from the pixel circuit PXC. The first electrodes ET1 may include a metal material such as aluminum (Al).

The common electrode connectors CVS may be disposed in the common voltage supply areas (for example, the first common voltage supply area CVA1 and/or the second common voltage supply area CVA2) of the non-display area NDA. The common electrode connectors CVS may be disposed on the pixel circuits PXC, respectively. Each of the common electrode connectors CVS may be integral with the pixel circuit PXC and may be an electrode exposed from the pixel circuit PXC. For example, each of the common electrode connectors CVS may protrude from the upper surface of the pixel circuit PXC. The common electrode connectors CVS may include a metal material such as aluminum (Al).

The first pads PD1 may be disposed in the first pad area PDA1 of the non-display area NDA. Each of the first pads PD1 may be connected to a circuit pad CPD1 of a circuit board 300 through a conductive connection member such as a wire WR. For example, the first pad PD1 and the circuit pad CPD1 may be electrically connected to each other through the wire WR.

The circuit board 300 may be a flexible printed circuit board (FPCB), a printed circuit board (PCB), a flexible printed circuit (FPC), a flexible film such as a chip-on-film (COF), or other circuit boards. Although not shown in the drawings, the semiconductor circuit substrate 101 and the circuit board 300 may be disposed on a separate underlying substrate. For example, the semiconductor circuit board 101 and the circuit board 300 may be attached to the upper surface of the lower substrate using an adhesive member such as a pressure sensitive adhesive.

The light-emitting element layer 200 may include the light-emitting elements LE, the second electrode ET2 and connection electrodes CNE. According to an embodiment, the light-emitting element layer 200 may further include additional elements. For example, the light-emitting element layer 200 may further include an organic film, a light-blocking layer and/or a reflective layer disposed between the light-emitting elements LE.

The light-emitting elements LE may be disposed on the first electrodes ET1, respectively. The light-emitting elements LE may be connected between the respective first electrodes ET1 and the second electrode ET2.

The light-emitting elements LE may be formed by being grown on a semiconductor substrate. Each of the light-emitting elements LE may be transferred onto the first electrode ET1 of the semiconductor circuit substrate 101 from a semiconductor substrate, or may be transferred onto the first electrode ET1 of the semiconductor circuit substrate 101 by an electrostatic manner using an electrostatic head or by a stamp manner using an elastic polymer material such as PDMS and silicon as a transfer substrate.

The light-emitting elements LE may include first semiconductor layers SEM1, SEM1a and SEM1b, active layers EML, EMLa and EMLb, and second semiconductor layers SEM2, SEM2a and SEM2b, respectively. The light-emitting elements LE may further include a passivation layer PSV and/or insulating layer INS, INSa and INSb. According to an embodiment, the light-emitting elements LE may further include contact electrodes CTE, CTEa and CTEb.

According to an embodiment, a pixel PX may include light-emitting elements LE having different structures. For example, the pixel PX may include the first light-emitting element LE1 having the structure according to at least one of the embodiments described above with reference to FIGS. 1 to 27, and a second light-emitting element LE2 and a third light-emitting element LE3 having a structure different from the structure of the first light-emitting element LE1. It should be understood, however, that the embodiments are not limited thereto. For example, at least one of the second light-emitting element LE2 and the third light-emitting element LE3 may have a structure substantially similar to or identical to that of the first light-emitting element LE1.

Although each of the light-emitting elements LE has vertical a side surface in the example shown in FIG. 31, the embodiments are not limited thereto. For example, at least one light-emitting element LE may include inclined a side surface such that the width gradually decreases or increases at least partially. For example, the passivation layer PSV of the first light-emitting element LE1 may include a side surface including an inclined surface (for example, the inclined surface ICS of FIG. 4).

The first light-emitting element LE1 may include a first semiconductor layer SEM1, a passivation layer PSV, an active layer EML, and a second semiconductor layer SEM2. The first light-emitting element LE1 may further include at least one of an etch stop layer EST, an insulating layer INS, and a contact electrode CTE. The first light-emitting element LE1 may have the structure and/or shape according to the above-described embodiments. The first semiconductor layer SEM1, the passivation layer PSV, the active layer EML, the second semiconductor layer SEM2, the etch stop layer EST, the insulating layer INS and the contact electrode CTE of the first light-emitting element LE1 may include the materials according to the above-described embodiments.

The passivation layer PSV of the first light-emitting element LE1 may include a semiconductor material having a lattice that matches or is identical to that of the semiconductor material contained in the active layer EML, and may surround the active layer EML. Accordingly, it is possible to suppress or reduce surface defects of the first light-emitting element LE1, and to improve the emission efficiency of the first light-emitting element LE1 and the pixel PX including it.

The passivation layer PSV of the first light-emitting element LE1 may be formed of a semiconductor material having a higher band gap energy than the semiconductor material contained in the active layer EML. Accordingly, it is possible to prevent or reduce non-emissive recombination of electrons and holes, and to improve the emission efficiency of the first light-emitting element LE1 and the pixel PX including it.

The second light-emitting element LE2 may include a first semiconductor layer SEM1a, an active layer EMLa and a second semiconductor layer SEM2a sequentially disposed in the thickness direction (for example, in the third direction DR3). The second light-emitting element LE2 may further include at least one of an insulating layer INSa and a contact electrode CTEa. The insulating layer INSa may surround the first semiconductor layer SEM1a, the active layer EMLa, and the second semiconductor layer SEM2a. The contact electrode CTEa may be disposed at an end of the second light-emitting element LE2 where the second semiconductor layer SEM2a is located. For example, the contact electrode CTEa may be disposed between the first electrode ET1 associated with the second light-emitting element LE2 and the second semiconductor layer SEM2a of the second light-emitting element LE2.

The third light-emitting element LE3 may include a first semiconductor layer SEM1b, an active layer EMLb and a second semiconductor layer SEM2b sequentially disposed in the thickness direction (for example, in the third direction DR3). The second light-emitting element LE2 may further include at least one of an insulating layer INSb and a contact electrode CTEb. The insulating layer INSb may surround the first semiconductor layer SEM1b, the active layer EMLb, and the second semiconductor layer SEM2b. The contact electrode CTEb may be disposed at an end of the third light-emitting element LE3 where the second semiconductor layer SEM2b is located. For example, the contact electrode CTEb may be disposed between the first electrode ET1 associated with the third light-emitting element LE3 and the second semiconductor layer SEM2b of the third light-emitting element LE3.

According to an embodiment, the second light-emitting element LE2 and the third light-emitting element LE3 may be inorganic light-emitting elements formed of an inorganic material. For example, the second light-emitting element LE2 and the third light-emitting element LE3 may be organic light-emitting diodes (inorganic LEDs) formed of phosphide semiconductor materials such as GaP, GaInP, AlGaP, AlInP, AlGaInP, AlP and InP; nitride semiconductor materials such as GaN, AlGaN, InGaN, AlInGaN, AlN and InN; or other inorganic materials.

According to an embodiment, the second light-emitting element LE2 may be a green LED (for example, a green micro LED) formed of a nitride semiconductor material and emitting green light. For example, the first semiconductor layer SEM1a, the active layer EMLa and the second semiconductor layer SEM2a of the second light-emitting element LE2 may include a nitride semiconductor material such as GaN, AlGaN, InGaN, AlInGaN, AlN, and InN. The first semiconductor layer SEM1a of the second light-emitting element LE2 may be a first conductivity type semiconductor layer doped to a first conductivity type (for example, n-type), and the second semiconductor layer SEM2a of the second light-emitting element LE2 may be a second conductivity type semiconductor layer doped to a second conductivity type (for example, p-type). The active layer EMLa of the second light-emitting element LE2 may be a green emissive layer having a multi-quantum well structure and emitting green light.

According to an embodiment, the third light-emitting element LE3 may be a blue LED (for example, a blue micro LED) formed of a nitride semiconductor material and emitting blue light. For example, the first semiconductor layer SEM1b, the active layer EMLb and the second semiconductor layer SEM2b of the third light-emitting element LE3 may include a nitride semiconductor material such as GaN, AlGaN, InGaN, AlInGaN, AlN, and InN. The first semiconductor layer SEM1b of the third light-emitting element LE3 may be a first conductivity type semiconductor layer doped to a first conductivity type (for example, n-type), and the second semiconductor layer SEM2b of the third light-emitting element LE3 may be a second conductivity type semiconductor layer doped to a second conductivity type (for example, p-type). The active layer EMLb of the third light-emitting element LE3 may be a blue emissive layer having a multi-quantum well structure and emitting blue light.

The insulating layers INSa and INSb of the second light-emitting element LE2 and the third light-emitting element LE3 may include at least one insulating material selected from silicon oxide (SiOₓ) (for example, SiO₂), silicon nitride (SiNₓ) (for example, Si₃N₄), aluminum oxide (AlₓO_{y}) (for example, Al₂O₃), titanium oxide (TiₓO_{y}) (for example, TiO₂) and hafnium oxide (HfOₓ), or other insulating materials. The insulating layers INS, INSa and INSb of the first light-emitting element LE1, the second light-emitting element LE2 and/or the third light-emitting element LE3 may include the same insulating material or different insulating materials.

The contact electrodes CTEa and CTEb of the second light-emitting element LE2 and the third light-emitting element LE3 may include metal, metal oxide, or other conductive material. The contact electrodes CTEa, CTEb and CTEb of the first light-emitting element LE1, the second light-emitting element LE2 and/or the third light-emitting element LE3 may include the same conductive material or different conductive materials. The contact electrodes CTE, CTEa, and CTEb may work as a bonding metal for adhering and/or connecting the light-emitting elements LE with the first electrodes ET1 during the fabrication process.

The second electrode ET2 may be disposed on the light-emitting elements LE. The second electrode ET2 may be a common electrode shared by the light-emitting elements LE and may be connected to the second semiconductor layers SEM2, SEM2a and SEM2b of the light-emitting elements LE.

The second electrode ET2 may be electrically connected to the common electrode connectors CVS of the semiconductor circuit substrate 101 through the connection electrodes CNE disposed in the common voltage supply areas (for example, the first common voltage supply area CVA1 and/or the second common voltage supply area CVA2). Accordingly, the second electrode ET2 may receive a common voltage through the common electrode connectors CVS of the semiconductor circuit board 101.

The connection electrodes CNE may be connected to the respective common electrode connectors CVS. For example, the connection electrodes CNE may be disposed on the common electrode connectors CVS, respectively. The connection electrodes CNE may be extended in the third direction DR3 and may be connected to the second electrodes ET2. For example, the height of the connection electrodes CNE may be substantially equal to that of the light-emitting elements LE.

The connection electrodes CNE may include a material electrically connected to the second electrode ET2. According to an embodiment, the connection electrodes CNE may be made of, but is not limited to, the same material as the contact electrodes CTE, CTEa and CTEb.

According to an embodiment, the display panel 100 may further include additional elements. For example, the display panel 100 may further include a passivation layer covering at least the light-emitting element layer 200 (for example, an encapsulation layer or an encapsulation substrate).

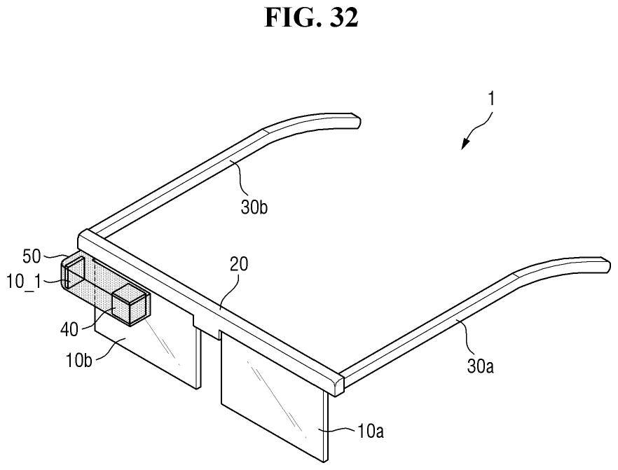

FIG. 32 is a view showing an example of a virtual reality device 1 including a display device 10_1 according to an embodiment.

Referring to FIG. 32, the virtual reality device 1 according to the embodiment may be a device in the form of glasses. The virtual reality device 1 according to the embodiment may include the display device 10_1, a left eye lens 10a, a right eye lens 10b, a support frame 20, eyeglass temples 30a and 30b, a reflective member 40, and a display case 50.

Although FIG. 32 shows the virtual reality device 1 including the eyeglass temples 30a and 30b, a head mounted display with a head strap, instead of the eyeglass temples 30a and 30b, may be employed as the virtual reality device 1 according to an embodiment. For example, the virtual reality device 1 according to the embodiment is not limited to that shown in FIG. 32 but may be applied in a variety of electronic devices in a variety of forms.

The display case 50 may include the display device 10_1 and the reflective member 40. An image displayed on the display device 10_1 may be reflected by the reflective member 40 and provided to the user's right eye through the right eye lens 10b. Accordingly, the user may watch a virtual reality image displayed on the display device 10_1 through the right eye.

Although the display case 50 is disposed at the right end of the support frame 20 in the example shown in FIG. 32, embodiments are not limited thereto. For example, the display case 50 may be disposed at the left end of the support frame 20. In such case, an image displayed on the display device 10_1 may be reflected by the reflective member 40 and provided to the user's left eye through the left eye lens 10a. Accordingly, the user may watch a virtual reality image displayed on the display device 10_1 through the left eye. By way of example, the display cases 50 may be disposed at both the left and right ends of the support frame 20, respectively. In such case, the user can watch a virtual reality image displayed on the display device 10_1 through both the left and right eyes.

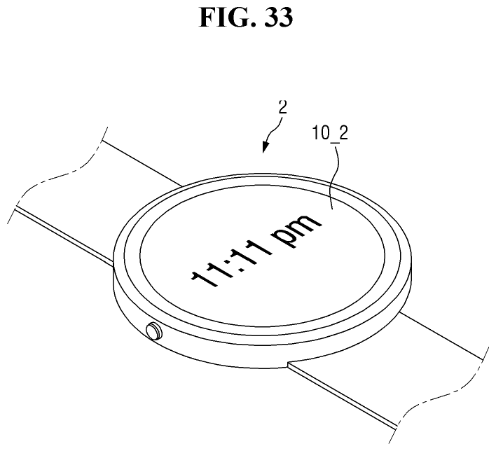

FIG. 33 is a view showing an example of a smart device including a display device 10_2 according to an embodiment.

Referring to FIG. 33, a display device 10_2 according to an embodiment may be applied to a smart watch 2 that is one of smart devices. The shape of a watch display unit of the smart watch 2 may follow the flat shape of the display device 10_2 when viewed from the top. For example, in case that the display device 10_2 according to the embodiment has a circular or elliptical shape when viewed from the top, the watch display unit of the smart watch 2 may have a circular or elliptical shape when viewed from the top. By way of example, in case that the display device 10_2 according to the embodiment has a rectangular shape when viewed from the top, the watch display unit of the smart watch 2 may have a rectangular shape when viewed from the top. It should be understood, however, that the disclosure is not limited thereto. The watch display unit of the smart watch 2 may not follow the shape of the display device 10_2 when viewed from the top.

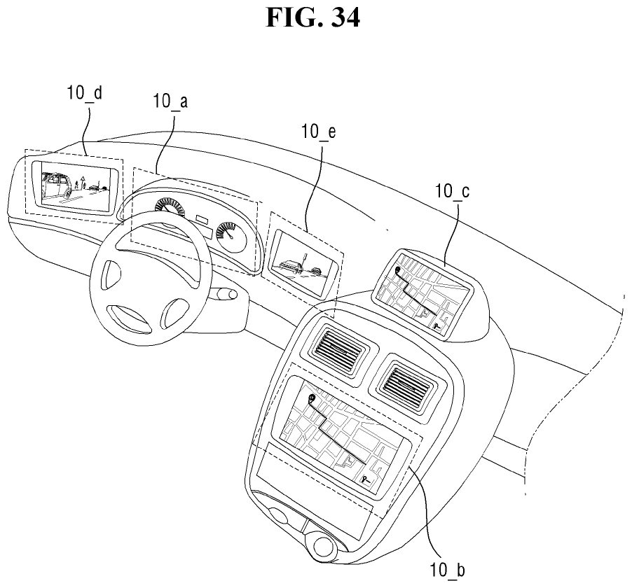

FIG. 34 shows an example of an instrument cluster and a center fascia for vehicles that include display devices 10_a, 10_b, 10_c, 10_d and 10_e according to an embodiment. FIG. 34 shows a vehicle in which display devices 10_a, 10_b, 10_c, 10_d and 10_e according to an embodiment are applied.

Referring to FIG. 34, the display devices 10_a, 10_b and 10_c according to an embodiment may be applied to the instrument cluster of a vehicle, may be applied to the center fascia of the vehicle, or may be applied to a center information display (CID) disposed on the dashboard of the vehicle. By way of example, the display devices 10_d and 10_e according to an embodiment may be applied to room mirror displays, which can replace side mirrors of the vehicle.

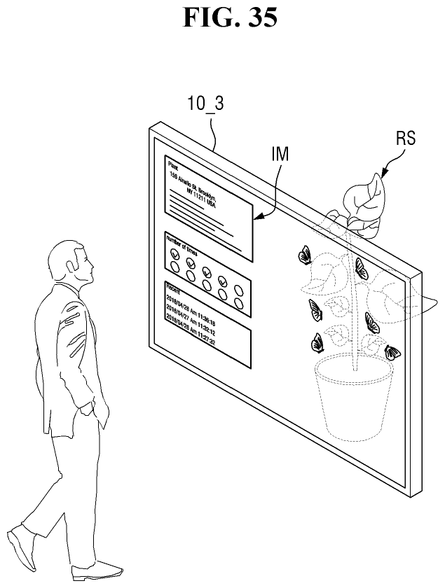

FIG. 35 is a view showing an example of a transparent display device including a display device 10_3 according to an embodiment.

Referring to FIG. 35, a display device 10_3 according to an embodiment may be applied to a transparent display device. The transparent display device may transmit light while displaying images IM. Accordingly, a user located on the front side of the transparent display device can not only view the images IM displayed on the display device 10_3 but also view an object RS or the background located on the rear side of the transparent display device. In case that the display device 10_3 is applied to the transparent display device, the display panel 100 may include a light-transmitting portion that can transmit light or may be formed on a substrate member made of a material that can transmit light.

In concluding the detailed description, those skilled in the art will appreciate that many variations and modifications can be made to the embodiments without substantially departing from the principles of the disclosure. Therefore, the disclosed embodiments are used in a generic and descriptive sense only and not for purposes of limitation.

What is claimed is:

1. A light-emitting element comprising:
a first semiconductor layer doped to a first conductivity type;
an active layer disposed on the first semiconductor layer;
a second semiconductor layer disposed on the active layer, the second semiconductor layer doped to a second conductivity type; and
a passivation layer surrounding surfaces of the active layer, the passivation layer comprising a side surface of the active layer, wherein
the passivation layer comprises a semiconductor material that matches a lattice of a semiconductor material contained in the active layer, and
the semiconductor material has a band gap energy higher than that of the semiconductor material contained in the active layer.

2. The light-emitting element of claim 1, wherein
the active layer comprises a quantum well layer containing GaInP and a barrier layer containing AlGaInP, and
the passivation layer is formed as a semiconductor layer containing AlInP.

3. The light-emitting element of claim 2, wherein the passivation layer is formed as an intrinsic semiconductor layer containing AlInP.

4. The light-emitting element of claim 1, wherein
The passivation layer is disposed between the first semiconductor layer and the second semiconductor layer, and
the passivation layer entirely surrounds the surfaces of the active layer comprising a first bottom surface, a second bottom surface, and the side surface of the active layer.

5. The light-emitting element of claim 4, wherein the passivation layer comprises:
a first passivation layer disposed between the first semiconductor layer and the active layer;
a second passivation layer disposed on a peripheral region of the first passivation layer and contacting the side surface of the active layer;
a third passivation layer disposed on a central region of the first passivation layer and contacting the first bottom surface of the active layer; and
a fourth passivation layer disposed on the active layer and contacting the second bottom surface of the active layer.

6. The light-emitting element of claim 5, further comprising:
an etch stop layer disposed between the first passivation layer and the second passivation layer and surrounding the third passivation layer.

7. The light-emitting element of claim 6, wherein the etch stop layer comprises an opening overlapping the active layer.

8. The light-emitting element of claim 6, wherein the etch stop layer is formed as an intrinsic semiconductor layer containing AlGaAs.

9. The light-emitting element of claim 1, wherein the passivation layer comprises a side surface comprising an inclined surface.

10. The light-emitting element of claim 1, further comprising:
an insulating layer disposed at a peripheral region of the passivation layer.

11. A display device comprising:
pixels, each of the pixels comprising a first electrode, a second electrode, and a light-emitting element electrically connected between the first electrode and the second electrode, wherein
the light-emitting elements comprises:
a first semiconductor layer doped to a first conductivity type;
an active layer disposed on the first semiconductor layer;
a second semiconductor layer disposed on the active layer and doped to a second conductivity type; and
a passivation layer surrounding surfaces of the active layer, the passivation layer comprising a side surface of the active layer,
the passivation layer comprises a semiconductor material that matches a lattice of a semiconductor material contained in the active layer, and
the semiconductor material has a band gap energy higher than that of the semiconductor material contained in the active layer.

12. The display device of claim 11, wherein
the active layer comprises a quantum well layer containing GaInP and a barrier layer containing AlGaInP, and
the passivation layer is formed as a semiconductor layer containing AlInP.

13. The display device of claim 11, wherein
the passivation layer is disposed between the first semiconductor layer and the second semiconductor layer, and
the passivation layer entirely surrounds the surfaces of the active layer comprising a first bottom surface, a second bottom surface, and the side surface of the active layer.

14. The display device of claim 13, wherein the passivation layer comprises:
a first passivation layer disposed between the first semiconductor layer and the active layer;
a second passivation layer disposed on a peripheral region of the first passivation layer and contacting the side surface of the active layer;
a third passivation layer disposed on a central region of the first passivation layer and contacting the first bottom surface of the active layer; and
a fourth passivation layer disposed on the active layer and contacting the second bottom surface of the active layer.

15. The display device of claim 14, wherein the light-emitting element further comprises an etch stop layer disposed between the first passivation layer and the second passivation layer and surrounding the third passivation layer.

16. The display device of claim 11, wherein the passivation layer comprises a side surface comprising an inclined surface.

17. A method of fabricating a light-emitting element, the method comprising:
sequentially forming a first semiconductor layer, a first passivation layer, an etch stop layer, a second passivation layer, and an insulating layer on a substrate;
etching a part of the insulating layer to expose a part of the second passivation layer;
exposing a part of the etch stop layer by etching the exposed part of the second passivation layer;
exposing a part of the first passivation layer by etching the exposed part of the etch stop layer; and
sequentially forming a third passivation layer, an active layer, a fourth passivation layer, and a second semiconductor layer on the exposed part of the first passivation layer.

18. The method of claim 17, wherein
the first passivation layer, the second passivation layer, the third passivation and the fourth passivation layer are formed by a semiconductor material that has a lattice identical to that of a semiconductor material contained in the active layer, and
the semiconductor material has a band gap energy higher than that of the semiconductor material contained in the active layer.

19. The method of claim 18, wherein
the forming of the active layer comprises alternately forming a barrier layer containing AlGaInP and a quantum well layer containing GaInP on the third passivation layer, and
the first passivation layer, the second passivation layer, the third passivation layer and the fourth passivation layer are formed using AlInP as a material.

20. The method of claim 17, further comprising:
forming a plurality of light-emitting elements simultaneously on the substrate; and
separating the light-emitting elements from one another at least partially after the second semiconductor layer has been formed.
